(19) United States
(12) Patent Application Publication
(10) Pub. No.: US 2025/0372469 A1
(43) Pub. Date: Dec. 4, 2025

(54) SEMICONDUCTOR DEVICE

(71) Applicant: ROHM CO., LTD., Kyoto (JP)

(72) Inventor: Bungo TANAKA, Kyoto-shi (JP)

(73) Assignee: ROHM CO., LTD., Kyoto (JP)

(21) Appl. No.: 19/296,510

(22) Filed: Aug. 11, 2025

Related U.S. Application Data
(63) Continuation of application No. PCT/JP2024/005656, filed on Feb. 19, 2024.

(30) Foreign Application Priority Data
Feb. 21, 2023 (JP) 2023-025219

(51) Int. Cl. H01L 23/31; H01L 23/00; H01L 23/498; H01L 23/528

(52) U.S. Cl. CPC H01L 23/3121; H01L 23/49838; H01L 23/5283; H01L 24/48; H01L 24/32; H01L 24/73; H01L 2224/32245; H01L 2224/48245; H01L 2224/73215

(57) ABSTRACT

A semiconductor device includes a semiconductor element, a second conductor, and an encapsulation resin. The semiconductor element includes an element front surface and an element back surface facing in opposite directions in a thickness-wise direction. The semiconductor element further includes an element insulation layer including an insulation front surface defining the element front surface and a first conductor disposed in the element insulation layer. The second conductor is separated from the first conductor in the thickness-wise direction. The encapsulation resin is in contact with the element insulation layer and encapsulates the semiconductor element and the second conductor. The first conductor and the second conductor are located at opposite sides of the element insulation layer and the encapsulation resin and are opposed to each other in the thickness-wise direction.

### CROSS-REFERENCE TO RELATED APPLICATIONS

This application is a continuation of, and claims the benefit of priority from International Application No. PCT/JP2024/005656, filed on Feb. 19, 2024, which claims the benefit of priority from Japanese Patent Application No. 2023-025219, filed on Feb. 21, 2023, the entire contents of each are incorporated herein by reference.

### BACKGROUND

The present disclosure relates to a semiconductor device.

A conventional semiconductor device includes a transformer used to transmit signals and power. Japanese Laid-Open Patent Publication No. 2018-78169 discloses an example of a transformer including two coils opposed to each other in a vertical direction.

### BRIEF DESCRIPTION OF THE DRAWINGS

FIG. 1 is a schematic circuit diagram showing the configuration of a signal transmission device including a first embodiment of a semiconductor device.

FIG. 2 is a schematic perspective view of the signal transmission device shown in FIG. 1.

FIG. 3 is a schematic perspective view of the semiconductor device shown in FIG. 2.

FIG. 4 is a schematic perspective view of the semiconductor device shown in FIG. 3 as viewed in a different direction.

FIG. 5 is a schematic plan view showing the structure of the semiconductor device shown in FIG. 3.

FIG. 6 is a schematic plan view showing the structure of a semiconductor element included in the semiconductor device shown in FIG. 5.

FIG. 7 is a schematic plan view showing the structure of the semiconductor device shown in FIG. 5 related to a second coil.

FIG. 8 is a schematic cross-sectional view taken along line 8-8 in FIG. 5.

FIG. 9 is a schematic cross-sectional view taken along line 9-9 in FIG. 5.

FIG. 10 is a schematic perspective view showing a modified example of a semiconductor device.

FIG. 11 is a schematic perspective view of the semiconductor device shown in FIG. 10 as viewed in a different direction.

FIG. 12 is a schematic cross-sectional view of the semiconductor device shown in FIG. 10.

FIG. 13 is a schematic perspective view showing a second embodiment of a semiconductor device.

FIG. 14 is a schematic perspective view of the semiconductor device shown in FIG. 13 as viewed in a different direction.

FIG. 15 is a schematic plan view showing the structure of the semiconductor device shown in FIG. 13.

FIG. 16 is a schematic plan view showing the structure of the semiconductor device shown in FIG. 13 related to a second coil.

FIG. 17 is a schematic cross-sectional view taken along line 17-17 in FIG. 15.

FIG. 18 is a schematic cross-sectional view taken along line 18-18 in FIG. 15.

FIG. 19 is a schematic perspective view showing a modified example of a semiconductor device.

FIG. 20 is a schematic perspective view of the semiconductor device shown in FIG. 19 as viewed in a different direction.

FIG. 21 is a schematic bottom view of the semiconductor device shown in FIG. 19.

FIG. 22 is a schematic cross-sectional view of the semiconductor device shown in FIG. 19.

FIG. 23 is a schematic perspective view showing a third embodiment of a semiconductor device.

FIG. 24 is a schematic perspective view of the semiconductor device shown in FIG. 23 as viewed in a different direction.

FIG. 25 is a schematic plan view showing the structure of the semiconductor device shown in FIG. 23.

FIG. 26 is a schematic plan view showing the structure of the semiconductor device shown in FIG. 23 related to a second coil.

FIG. 27 is a schematic cross-sectional view taken along line 27-27 in FIG. 25.

FIG. 28 is a schematic cross-sectional view taken along line 28-28 in FIG. 25.

FIG. 29 is a schematic bottom view showing a modified example of a semiconductor device.

FIG. 30 is a schematic cross-sectional view of the semiconductor device shown in FIG. 29.

FIG. 31 is a schematic plan view showing a modified example of a semiconductor device.

FIG. 32 is a schematic cross-sectional view of the semiconductor device shown in FIG. 31.

FIG. 33 is a schematic plan view showing a modified example of a semiconductor device.

FIG. 34 is a schematic cross-sectional view of the semiconductor device shown in FIG. 33.

### DETAILED DESCRIPTION

Embodiments of a signal transmission device and a semiconductor device according to the present disclosure will now be described with reference to the accompanying drawings.

In the drawings, components may not be drawn to scale for simplicity and clarity of illustration. To aid understanding, hatching lines may not be shown in the cross-sectional drawings. The accompanying drawings illustrate exemplary embodiments in accordance with the present disclosure and are not intended to limit the present disclosure. Terms such as “first,” “second,” and “third” in this disclosure are used to distinguish subjects and not used for ordinal purposes.

The following detailed description includes exemplary embodiments of a device, a system, and a method according to the present disclosure. The detailed description is illustrative and is not intended to limit embodiments of the present disclosure or the application and use of the embodiments.

In this specification, the phrase “at least one of” as used in this disclosure means “one or more” of a desired choice. As an example, the phrase “at least one” as used in this description means “only one of the options” or “both of the two options” if the number of options is two. In another example, the phrase “at least one of” as used in this description means “only one single option” or “any combination of two or more options” if the number of options is three or more.

### First Embodiment

### Schematic Structure of Signal Transmission Device

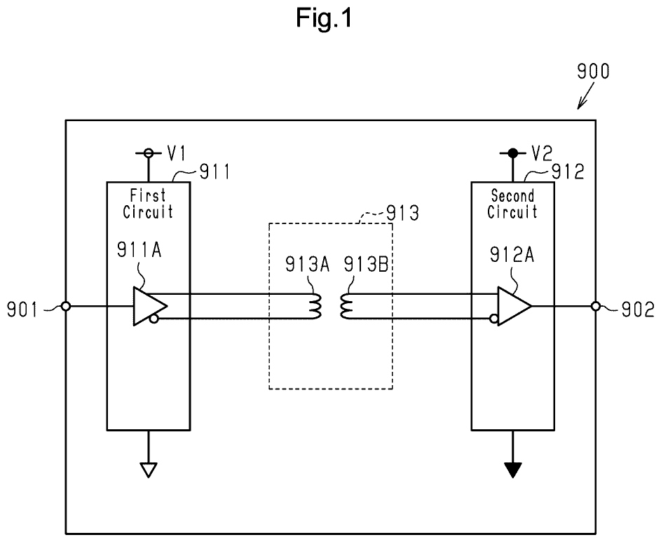

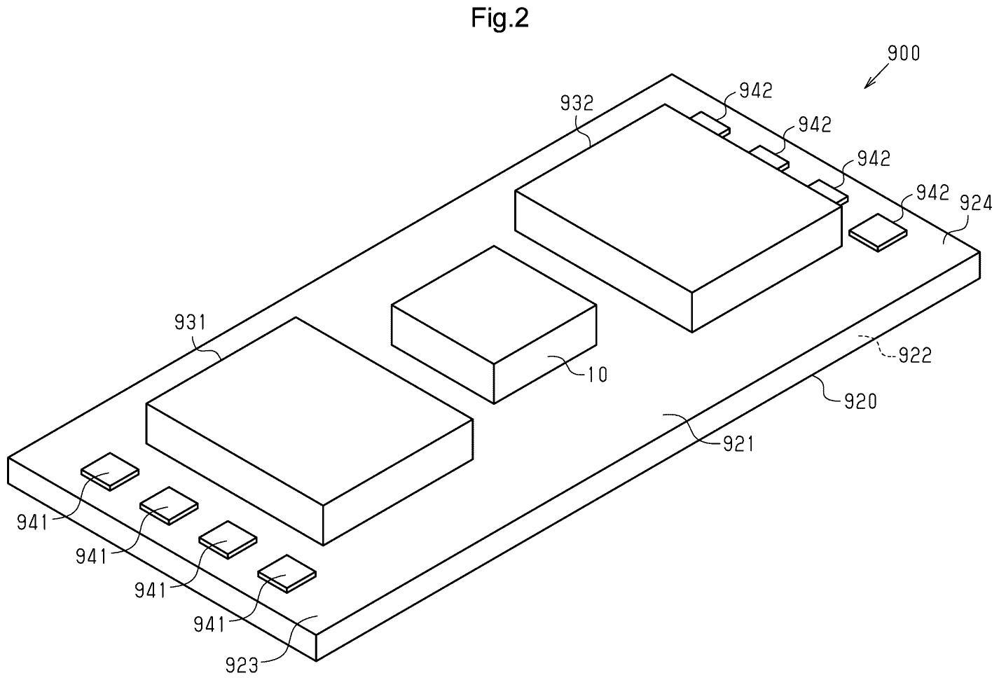

The schematic structure of a signal transmission device 900 will now be described with reference to FIGS. 1 and 2. FIG. 1 is a simplified diagram showing an example of the circuit configuration of the signal transmission device 900. FIG. 2 is a schematic perspective view of the signal transmission device 900.

As shown in FIG. 1, the signal transmission device 900 is configured to transmit a pulse signal while electrically insulating a first terminal 901 and a second terminal 902. The signal transmission device 900 is, for example, a digital isolator. The signal transmission device 900 includes a first circuit 911 electrically connected to the first terminal 901, a second circuit 912 electrically connected to the second terminal 902, and a transformer 913 electrically insulating the first circuit 911 and the second circuit 912.

The first circuit 911 is configured to be activated by the application of a first voltage V1. The first circuit 911 is, for example, electrically connected to an external controller (not shown). The first circuit 911 includes a transmission circuit 911A. The second circuit 912 is configured to be activated by the application of a second voltage V2 that differs from the first voltage V1. The second voltage V2 is, for example, greater than the first voltage V1. The first voltage V1 and the second voltage V2 are direct current voltages. The second circuit 912 is, for example, electrically connected to a drive circuit that is a subject controlled by the controller. An example of the drive circuit is a switching circuit. The second circuit 912 includes a reception circuit 912A. The ground of the first circuit 911 is independent of the ground of the second circuit 912.

The transformer 913 is connected between the transmission circuit 911A and the reception circuit 912A. The transformer 913 includes two coils 913A and 913B. The coil 913A is connected to the transmission circuit 911A. The coil 913B is connected to the reception circuit 912A.

In an example, the controller inputs a control signal into the transmission circuit 911A of the first circuit 911 through the first terminal 901. The reception circuit 912A of the second circuit 912 receives the control signal from the transmission circuit 911A of the first circuit 911 through the transformer 913. The signal transmitted to the second circuit 912 is output from the second circuit 912 to the drive circuit through the second terminal 902. The first terminal 901 may be referred to as an input terminal that inputs a signal into the signal transmission device 900. The second terminal 902 may be referred to as an output terminal that outputs a signal from the signal transmission device 900.

As described above, in the signal transmission device 900, the transformer 913 electrically insulates the first circuit 911 and the second circuit 912. More specifically the transformer 913 restricts transmission of DC voltage between the first circuit 911 and the second circuit 912. The transformer 913 allows transmission of pulse signals between the first circuit 911 and the second circuit 912.

A state in which the first circuit 911 is insulated from the second circuit 912 refers to a state in which transmission of DC voltage between the first circuit 911 and the second circuit 912 is blocked, while transmission of a pulse signal from the first circuit 911 to the second circuit 912 is allowed. Thus, the second circuit 912 is configured to receive a signal from the first circuit 911.

As shown in FIG. 2, the signal transmission device 900 includes a substrate 920 and semiconductor devices 931, 932, and 10.

The substrate 920 has the form of, for example, a rectangular plate. The substrate 920 includes a substrate front surface 921 and a substrate back surface 922 facing in opposite directions. The substrate front surface 921 and the substrate back surface 922 are, for example, rectangular.

First terminals 941 and second terminals 942 are formed on the substrate front surface 921. The first terminals 941 and the second terminals 942 are formed from a material including, for example, copper (Cu). The first terminals 941 are arranged on a first end 923 of the substrate 920. The second terminals 942 are arranged on a second end 924 of the substrate 920 opposite from the first end 923.

The first terminals 941 include a power terminal configured to supply the first voltage V1 shown in FIG. 1, a ground terminal connected to the ground of the first circuit 911, and the first terminal 901. The second terminals 942 include a power terminal configured to supply the second voltage V2 shown in FIG. 1, a ground terminal connected to the ground of the second circuit 912, and the second terminal 902.

The semiconductor devices 931, 932, and 10 are mounted on the substrate front surface 921 of the substrate 920. In an example, the semiconductor devices 931, 932, and 10 are connected to pads (not shown) formed on the substrate front surface 921. The pads are connected to the first terminals 941 and the second terminals 942 by interconnects (not shown). The substrate 920 is formed of, for example, a semiconductor substrate, an insulating substrate formed from a material including epoxy resin, an insulating substrate formed from a material including glass, or an insulating substrate formed from a material including ceramics such as alumina.

The semiconductor device 931 includes the first circuit 911 shown in FIG. 1. The semiconductor device 932 includes the second circuit 912 shown in FIG. 1 The semiconductor device 10 includes the transformer 913 shown in FIG. 1. The semiconductor devices 931, 932, and 10 may each be referred to as a semiconductor chip. The signal transmission device 900 may be referred to as a semiconductor module. The signal transmission device 900 may be referred to as a multi-chip module including multiple semiconductor chips.

The semiconductor device 10 including the transformer 913 may be referred to as an isolation chip disposed between the semiconductor device 931 including the first circuit 911 and the semiconductor device 932 including the second circuit 912 to insulate the semiconductor device 931 from the semiconductor device 932. The semiconductor devices 931, 932, and 10 are arranged in the order of the semiconductor device 931 including the first circuit 911, the semiconductor device 10 including the transformer 913, and the semiconductor device 932 including the second circuit 912 in a direction from the first terminals 941 toward the second terminals 942.

The signal transmission device 900 may include an encapsulation member encapsulating the semiconductor devices 931, 932, and 10 mounted on the substrate front surface 921. In an example, the encapsulation member may be a case accommodating the substrate 920 and the semiconductor devices 931, 932, and 10. The case may be filled with a resin such as silicone resin. In another example, the encapsulation member may be an encapsulation resin covering at least the semiconductor devices 931, 932, and 10. The encapsulation resin may be, for example, a molding resin including an epoxy resin.

### Semiconductor Device Including Transformer

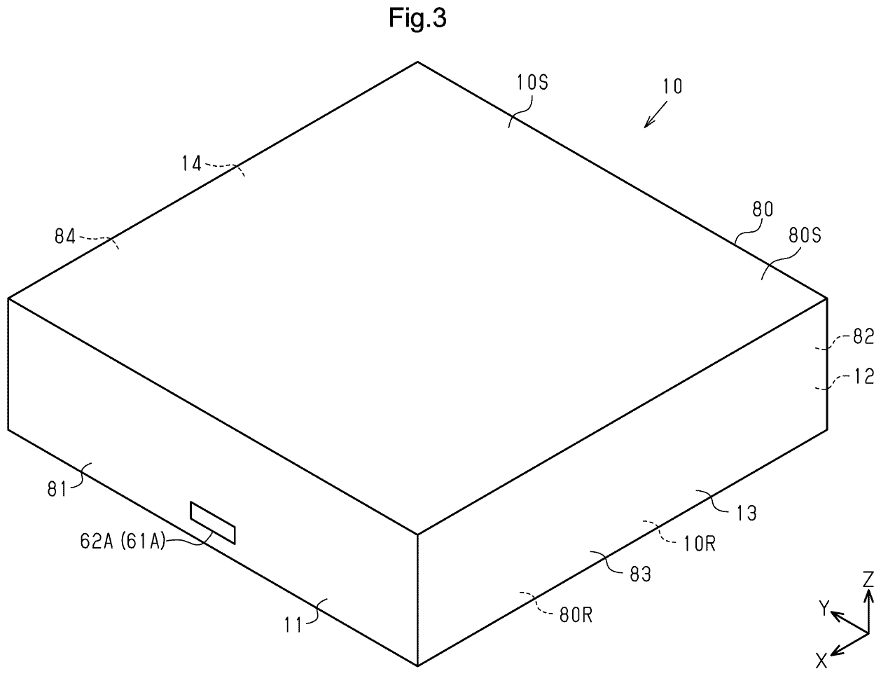

The structure of the semiconductor device 10 will be described with reference to FIGS. 3 to 9.

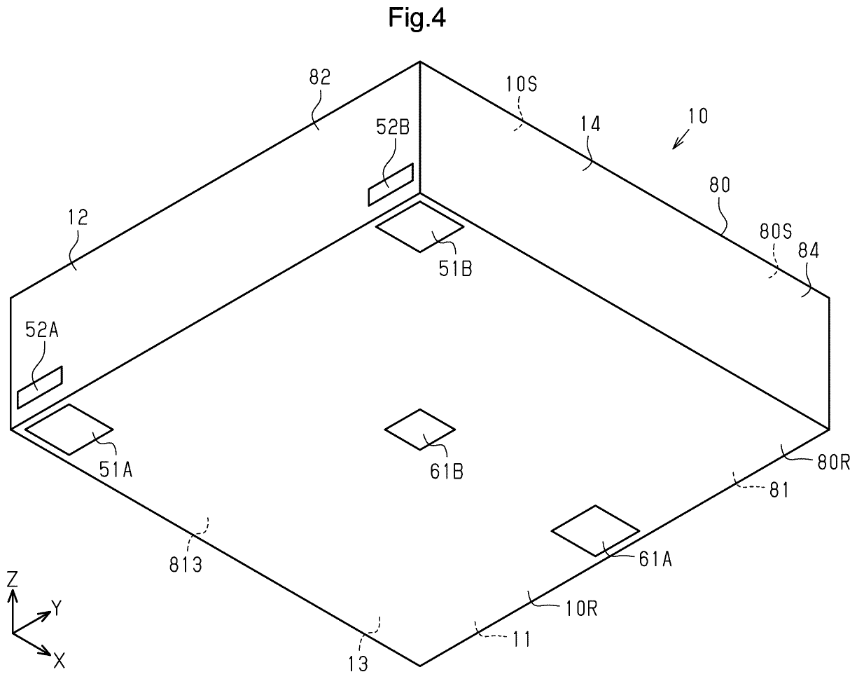

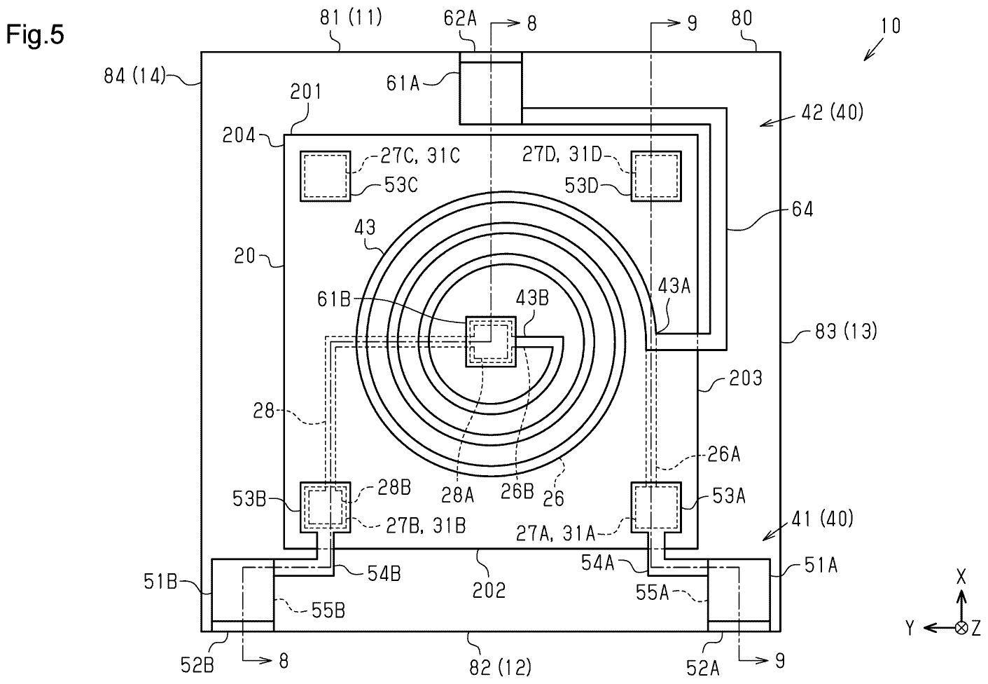

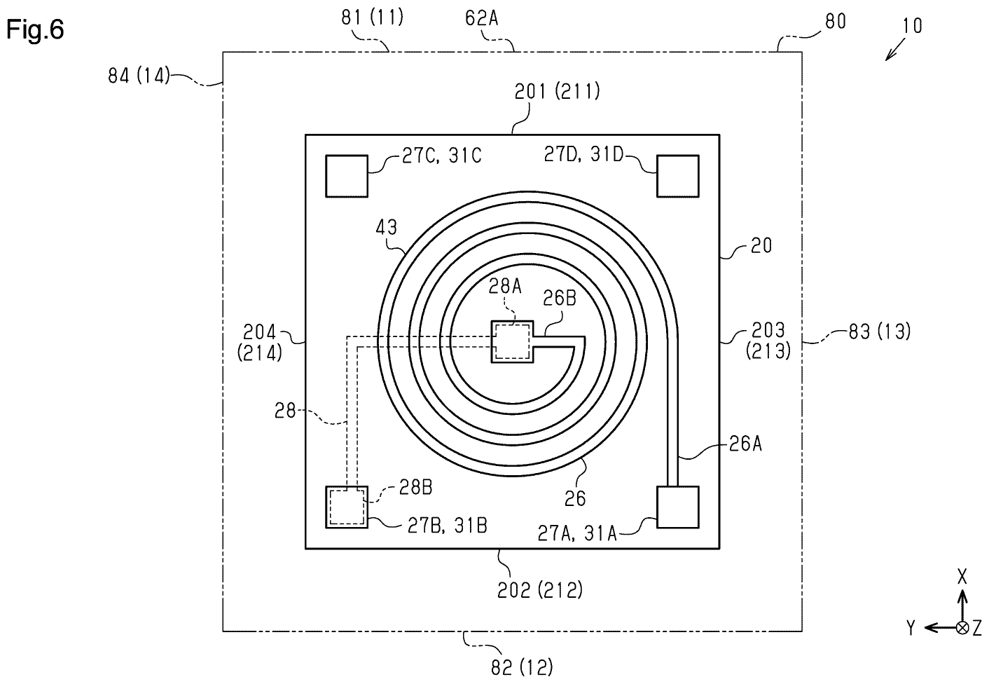

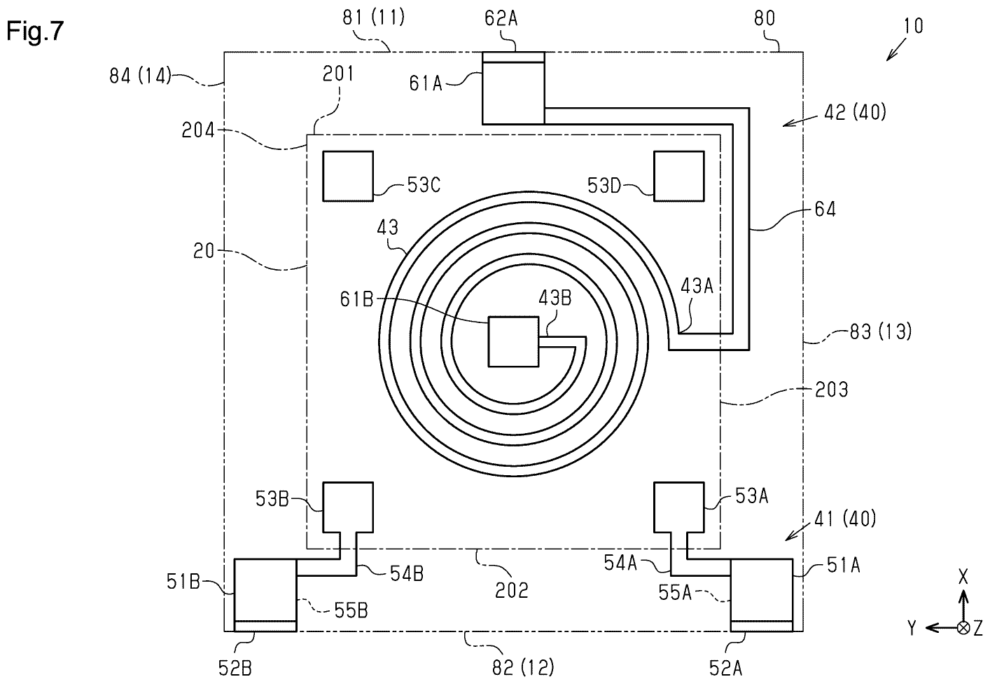

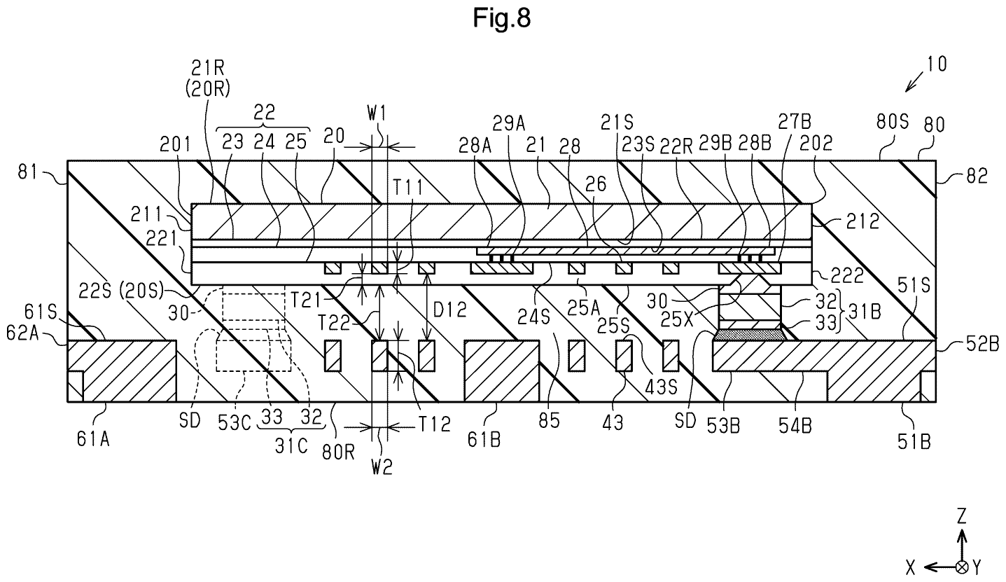

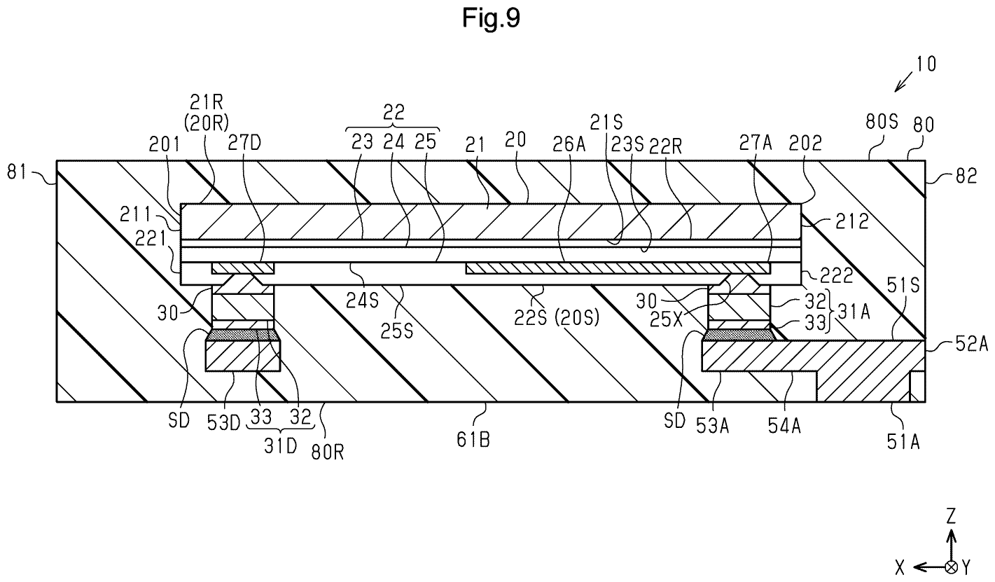

FIGS. 3 and 4 are perspective views showing the exterior of the semiconductor device 10. FIG. 3 is an upper perspective view of the semiconductor device 10, and FIG. 4 is a lower perspective view of the semiconductor device 10. FIG. 5 is a plan view showing the lower side of the semiconductor device 10. In FIG. 5, an encapsulation resin 80 and an element insulation layer 22 are shown transparently. FIG. 6 is a plan view of a semiconductor element 20. In FIG. 6, the element insulation layer 22 is shown transparently. FIG. 7 is a plan view of a conductor 40. In FIG. 7, the encapsulation resin 80 is shown transparently. In FIG. 7, the contour of the semiconductor element 20 is indicated by single-dashed lines. FIG. 8 is a schematic cross-sectional view of the semiconductor device 10 taken along line 8-8 in FIG. 5. FIG. 9 is a schematic cross-sectional view of the semiconductor device 10 taken along line 9-9 in FIG. 5. For the sake of convenience, FIGS. 8 and 9 may show a member that is not present on the line indicating the cross-sectional position. Further, the position and size of a member may differ from those shown in FIGS. 5 to 7.

### General Structure of Semiconductor Device

As shown in FIGS. 3 and 4, the semiconductor device 10 is, for example, rectangular-box-shaped. In the description hereafter, the thickness-wise direction of the semiconductor device 10 is referred to as a z-direction. A direction orthogonal to the z-direction is referred to as an x-direction. A direction orthogonal to the z-direction and the x-direction is referred to as a y-direction. A view of an object taken in the z-direction is referred to as a plan view.

The semiconductor device 10 includes a device upper surface 10S, a device lower surface 10R, and device side surfaces 11, 12, 13, and 14. The device upper surface 10S and the device lower surface 10R face in opposite directions in the z-direction. The device side surfaces 11, 12, 13, and 14 each intersect the device upper surface 10S and the device lower surface 10R. The device side surfaces 11 and 12 face in opposite directions in the x-direction. The device side surfaces 13 and 14 face in opposite directions in the y-direction.

As shown in FIGS. 3 to 9, the semiconductor device 10 includes the semiconductor element 20, the conductor 40, a bonding portion SD, and the encapsulation resin 80. The semiconductor element 20 includes a first coil 26. The conductor 40 includes a second coil 43 and external connection terminals 51A, 51B, 61A, and 61B. The first coil 26 and the second coil 43 correspond to the coils 913A and 913B shown in FIG. 1. The semiconductor element 20 is mounted on the conductor 40. The first coil 26 of the semiconductor element 20 is opposed to the second coil 43 of the conductor 40 in the z-direction. As shown in FIG. 4, the external connection terminals 51A, 51B, 61A, and 61B are exposed from a resin lower surface 80R of the encapsulation resin 80. The semiconductor device 10 is mounted on the substrate 920, which is shown in FIG. 2, via the external connection terminals 51A, 51B, 61A, and 61B.

### Semiconductor Element

As shown in FIGS. 6, 8, and 9, the semiconductor element 20 includes an element front surface 20S, an element back surface 20R, and element side surfaces 201, 202, 203, and 204. The element front surface 20S and the element back surface 20R face in opposite directions in the z-direction. The element front surface 20S and the resin lower surface 80R face in the same direction. The semiconductor element 20 is arranged so that the element front surface 20S and the resin lower surface 80R face in the same direction. The element side surfaces 201, 202, 203, and 204 each intersect the element front surface 20S and the element back surface 20R. In an example, the element side surfaces 201, 202, 203, and 204 are orthogonal to the element front surface 20S and the element back surface 20R. The element side surfaces 201 and 202 face in opposite directions in the x-direction. The element side surfaces 203 and 204 face in opposite directions in the y-direction.

As shown in FIGS. 8 and 9, the semiconductor element 20 includes an element substrate 21. The element substrate 21 is a semiconductor substrate and is formed from a material including, for example, silicon (Si). In the present embodiment, the element substrate 21 is a Si substrate.

The element substrate 21 includes a substrate main surface 21S, a substrate back surface 21R, and substrate side surfaces 211, 212, 213, and 214. The substrate main surface 21S and the substrate back surface 21R face in opposite directions in the z-direction. As shown in FIGS. 3 and 4, the substrate side surfaces 211 and 212 face in opposite directions in the x-direction. The substrate side surfaces 213 and 214 face in opposite directions in the y-direction. The substrate main surface 21S is opposed to the element connectors 53A and 53B, dummy element connectors 53C and 53D, and the second coil 43 of the conductor 40. The substrate back surface 21R and a resin upper surface 80S face in the same direction.

The element insulation layer 22 covers the substrate main surface 21S. The element insulation layer 22 includes an insulation front surface 22S, an insulation back surface 22R, and insulation side surfaces 221, 222, 223, and 224. The insulation front surface 22S of the element insulation layer 22 and the substrate main surface 21S face in the same direction. The insulation back surface 22R of the element insulation layer 22 and the insulation front surface 22S of the element insulation layer 22 face in opposite directions. The insulation back surface 22R of the element insulation layer 22 faces the substrate main surface 21S and is in contact with the substrate main surface 21S. The insulation side surfaces 221, 222, 223, and 224 of the element insulation layer 22 and the element side surfaces 201, 202, 203, and 204 face in the same direction, respectively. The insulation front surface 22S of the element insulation layer 22 defines the element front surface 20S of the semiconductor element 20. The substrate back surface 21R of the element substrate 21 defines the element back surface 20R of the semiconductor element 20. The substrate side surfaces 211 to 214 of the element substrate 21 and the insulation side surfaces 221 to 224 of the element insulation layer 22 define the element side surfaces 201 to 204 of the semiconductor element 20.

The semiconductor element 20 includes a first coil 26. The first coil 26 corresponds to a “first conductor.” The first coil 26 is spiral in plan view. The first coil 26 includes a first end 26A located outward and a second end 26B located inward. The first end 26A corresponds to an “outer end.” The second end 26B corresponds to an “inner end.”

The first coil 26 is disposed in the element insulation layer 22. In an example, the element insulation layer 22 includes three insulation layers 23, 24, and 25. The insulation layers 23, 24, and 25 are stacked on the substrate main surface 21S of the element substrate 21 in the order of the insulation layers 23, 24, and 25. The first coil 26 is formed on a front surface 24S of the second insulation layer 24. The first coil 26 and the front surface 24S of the second insulation layer 24 are covered by the third insulation layer 25.

The element insulation layer 22 is insulating. The first insulation layer 23 and the second insulation layer 24 are formed from a material including, for example, silicon (Si). The first insulation layer 23 and the second insulation layer 24 are formed from, for example, silicon oxide (SiO₂) or silicon nitride (SiN). The third insulation layer 25 is formed from, for example, an insulating resin such as a polyimide resin, a phenol resin, or an epoxy resin. Alternatively, the third insulation layer 25 may be formed from a material including, for example, Si.

The semiconductor element 20 includes connection pads 27A, 27B, 27C, and 27D. The connection pads 27A to 27D and the first coil 26 are located at the same position in the z-direction. The connection pads 27A to 27D are arranged on the front surface 24S of the second insulation layer 24. The third insulation layer 25 covers the surroundings of the connection pads 27A to 27D. The third insulation layer 25 includes openings 25X partially exposing the connection pads 27A to 27D.

As shown in FIG. 6, the connection pad 27A is electrically connected to the first end 26A of the first coil 26. The connection pad 27B is electrically connected to the second end 26B of the first coil 26 by an element interconnect 28. Thus, the first coil 26 is connected between the connection pad 27A and the connection pad 27B. The first coil 26 is electrically disconnected from the connection pad 27C and the connection pad 27D. The connection pads 27C and 27D, electrically disconnected from the first coil 26, each correspond to “a dummy connection pad.”

As shown in FIG. 8, the element interconnect 28 is formed on a front surface 23S of the first insulation layer 23. The element interconnect 28 is formed from a material including, for example, Cu or aluminum (Al). The element interconnect 28 includes a first end 28A electrically connected to the first coil 26 by a via 29A. The element interconnect 28 includes a second end 28B electrically connected to the connection pad 27B by a via 29B. The vias 29A and 29B extend through the second insulation layer 24. The vias 29A and 29B are formed from a material including Cu, Al, or tungsten (W).

The semiconductor element 20 includes element electrodes 31A, 31B, 31C, and 31D electrically connected to the connection pads 27A, 27B, 27C, and 27D. The element electrodes 31A, 31B, 31C, and 31D are electrically connected to the connection pads 27A, 27B, 27C, and 27D, respectively, by connection interconnects 30. The element electrodes 31A to 31D overlap the connection pads 27A to 27D in plan view.

The connection pads 27A and 27B are electrically connected to the first coil 26. Thus, the element electrodes 31A and 31B electrically connected to the connection pads 27A and 27B are electrically connected to the first coil 26. The connection pads 27C and 27D are electrically disconnected from the first coil 26. Therefore, the element electrodes 31C and 31D electrically connected to the connection pads 27C and 27D are electrically disconnected from the first coil 26. The element electrodes 31C and 31D electrically disconnected from the first coil 26 each correspond to a “dummy element electrode.”

The element electrodes 31A to 31D include a conductive layer 32 and a barrier layer 33. The conductive layer 32 is formed from a material including, for example, Cu. The conductive layer 32 may be formed of multiple metal layers. The conductive layer 32 may include a seed layer. The seed layer is formed from, for example, titanium (Ti)/Cu. The barrier layer 33 is formed from a material including Ni. The barrier layer 33 may be formed of multiple metal layers. The barrier layer 33 is formed from, for example, nickel (Ni), palladium (Pd), gold (Au), or an alloy including two or more of these metals.

### Conductor

As shown in FIGS. 7, 8, and 9, the conductor 40 includes a first wiring member 41, a second wiring member 42, and the second coil 43.

The first wiring member 41 includes a first external connection terminal 51A, a second external connection terminal 51B, a first element connector 53A, a second element connector 53B, a first interconnect 54A, and a second interconnect 54B. The second wiring member 42 includes a third external connection terminal 61A, a fourth external connection terminal 61B, and a third interconnect 64. The third interconnect 64 corresponds to a “second lead wire.”

As shown in FIG. 7, the first external connection terminal 51A, the second external connection terminal 51B, the third external connection terminal 61A, and the fourth external connection terminal 61B are each quadrilateral in plan view. The shape of the first external connection terminal 51A, the second external connection terminal 51B, the third external connection terminal 61A, and the fourth external connection terminal 61B may be changed in any manner and may be, for example, circular or polygonal in plan view. As shown in FIGS. 8 and 9, the first external connection terminal 51A, the second external connection terminal 51B, the third external connection terminal 61A, and the fourth external connection terminal 61B are exposed from the resin lower surface 80R of the encapsulation resin 80.

As shown in FIG. 5, in an example, the first external connection terminal 51A and the second external connection terminal 51B are arranged along the device side surface 12 of the semiconductor device 10. The first external connection terminal 51A and the second external connection terminal 51B may be separated in the y-direction. The first external connection terminal 51A and the second external connection terminal 51B are arranged in the y-direction in plan view. The first external connection terminal 51A is located at the corner formed of the device side surface 12 and the device side surface 13 of the semiconductor device 10. The second external connection terminal 51B is located at the corner of the device side surface 12 and the device side surface 14 of the semiconductor device 10.

The first external connection terminal 51A includes a joining portion 52A. The joining portion 52A extends toward the device side surface 12 and is exposed from the device side surface 12. The second external connection terminal 51B includes a joining portion 52B. The joining portion 52B extends toward the device side surface 12 and is exposed from the device side surface 12.

As shown in FIGS. 5 and 7, the first element connector 53A and the second element connector 53B overlap the semiconductor element 20 in plan view. The first element connector 53A and the second element connector 53B overlap the element electrodes 31A and 31B of the semiconductor element 20 in the z-direction.

The first element connector 53A and the second element connector 53B are each quadrilateral in plan view. The shape of the first element connector 53A and the second element connector 53B may be changed in any manner and may be, for example, circular or polygonal in plan view.

The first element connector 53A is electrically connected to the first external connection terminal 51A by the first interconnect 54A. The second element connector 53B is electrically connected to the second external connection terminal 51B by the second interconnect 54B.

The third external connection terminal 61A may be arranged at the device side surface 11 of the semiconductor device 10. In an example, in plan view, the third external connection terminal 61A is located at the center of the device side surface 11 in the y-direction. The position of the third external connection terminal 61A may be changed in any manner. In an example, the third external connection terminal 61A may be located at the corner formed of the device side surface 11 and the device side surface 13 of the semiconductor device 10 or the corner formed of the device side surface 11 and the device side surface 14. The third external connection terminal 61A includes a joining portion 62A. The joining portion 62A extends toward the device side surface 11 and is exposed from the device side surface 11.

As shown in FIGS. 4, 5, and 7, the fourth external connection terminal 61B is located in the center of the semiconductor device 10 in plan view. In an example, the third external connection terminal 61A and the fourth external connection terminal 61B are located at the same position in the y-direction. That is, the third external connection terminal 61A and the fourth external connection terminal 61B are arranged in the x-direction.

As shown in FIG. 7, the second coil 43 is spiral in plan view. The second coil 43 includes a first end 43A located outward and a second end 43B located inward. The first end 43A corresponds to an “outer end.” The second end 43B corresponds to an “inner end.”

The first end 43A of the second coil 43 is electrically connected to the third external connection terminal 61A by the third interconnect 64. The second end 43B of the second coil 43 is electrically connected to the fourth external connection terminal 61B.

As shown in FIGS. 5 and 7, the conductor 40 includes the dummy element connectors 53C and 53D. The dummy element connectors 53C and 53D overlap the semiconductor element 20 in plan view. The dummy element connectors 53C and 53D overlap the element electrodes 31C and 31D of the semiconductor element 20 in the z-direction. The dummy element connectors 53C and 53D are connected to, for example, the third interconnect 64, the third external connection terminal 61A, or the like by a connection lead (not shown). The dummy element connectors 53C and 53D are located at the same position as the element connectors 53A and 53B in the z-direction. The dummy element connectors 53C and 53D are held at the same position as the element connectors 53A and 53B in the z-direction by the connection lead.

As shown in FIGS. 8 and 9, the second coil 43, the element connectors 53A and 53B, the dummy element connectors 53C and 53D, and the interconnects 54A, 54B, and 64 of the conductor 40 are located at the same position in the z-direction. In an example, the upper surfaces of the second coil 43, the element connectors 53A and 53B, the dummy element connectors 53C and 53D, and the interconnects 54A, 54B, and 64 are located at the same position as upper surfaces 51S and 61S of the external connection terminals 51A, 51B, 61A, and 61B in the z-direction.

In an example, the conductor 40 includes a lead frame. The lead frame is formed from a material including Cu. In an example, a Cu plate is etched to form a frame, and the conductor 40 is connected to the frame. The conductor 40 is cut at the joining portions 52A, 52B, and 62A and separated from the frame subsequent to formation of the encapsulation resin 80.

The second coil 43, which is formed of the lead frame, has a thickness T12 in the z-direction. The first coil 26, which is formed by semiconductor processing, has a thickness T11. The thickness T12 is greater than the thickness T11

As shown in FIGS. 8 and 9, the first coil 26 has a width W1 in a direction parallel to the element front surface 20S. The width W1 is defined as, for example, the dimension in the x-direction. The second coil 43 has a width W2 in a direction parallel to the element front surface 20S. The width W2 is defined as, for example, the dimension in the x-direction. The width W1 of the first coil 26 corresponds to a “first width-wise dimension.” The width W2 of the second coil 43 corresponds to a “second width-wise dimension.” For example, the width W1 of the first coil 26 is equal to the width W2 of the second coil 43. The width W1 of the first coil 26 may be smaller than the width W2 of the second coil 43. The width W1 of the first coil 26 may be larger than the width W2 of the second coil 43.

### Bonding Portion

As shown in FIGS. 8 and 9, the element electrodes 31A and 31B of the semiconductor element 20 are electrically connected to the element connectors 53A and 53B by the bonding portions SD. The element electrodes 31C and 31D of the semiconductor element 20 are electrically connected to the dummy element connectors 53C and 53D by the bonding portions SD. The bonding portion SD is, for example, a solder layer. The solder layer is formed from a material including tin (Sn). The solder layer is formed from Sn, a Sn-silver (Ag)-based alloy, and a Sn-antimony (Sb)-based alloy.

The semiconductor element 20 is connected to the element connectors 53A and 53B and the dummy element connectors 53C and 53D by the bonding portions SD. The element front surface 20S of the semiconductor element 20 is separated from the upper surfaces of the element connectors 53A and 53B and the dummy element connectors 53C and 53D. Thus, the element front surface 20S of the semiconductor element 20 is separated from the second coil 43, which is located at the same position as the element connectors 53A and 53B and the dummy element connectors 53C and 53D in the z-direction.

### Encapsulation Resin

The encapsulation resin 80 encapsulates the semiconductor element 20, the conductor 40, and the bonding portions SD.

As shown in FIGS. 3 and 4, the encapsulation resin 80 defines the exterior surface of the semiconductor device 10.

The encapsulation resin 80 includes the resin upper surface 80S, the resin lower surface 80R, and resin side surfaces 81, 82, 83, and 84. The resin upper surface 80S and the resin lower surface 80R face in opposite directions in the z-direction. The resin side surfaces 81, 82, 83, and 84 are orthogonal to the resin upper surface 80S and the resin lower surface 80R. The resin side surfaces 81 and 82 face in opposite directions in the x-direction. The resin side surfaces 83 and 84 face in opposite directions in the y-direction.

The encapsulation resin 80 is formed from, for example, an electrically insulating resin. The resin may be, for example, a synthetic resin of which the base component is an epoxy resin. The encapsulation resin 80 may be formed from, for example, a synthetic resin including a filler. The filler is formed from, for example, SiO₂. The encapsulation resin 80 is, for example, colored black. The material properties and shape of the encapsulation resin 80 are not limited.

As shown in FIGS. 8 and 9, the encapsulation resin 80 is in contact with the element front surface 20S, the element back surface 20R, the element side surfaces 201 to 204 of the semiconductor element 20. The encapsulation resin 80 is in contact with the surface of the conductor 40. The encapsulation resin 80 encapsulates the semiconductor element 20 and the second coil 43. The second coil 43 is separated from the element front surface 20S of the semiconductor element 20. Thus, the encapsulation resin 80 includes a resin portion 85 located between the element front surface 20S of the semiconductor element 20 and the second coil 43.

The resin portion 85 has a thickness T22 that is greater than the thickness of the third insulation layer 25 covering the first coil 26 of the semiconductor element 20. More specifically, the resin portion 85 has a thickness T22 that is greater than a thickness T21 of an element resin portion 25A of the third insulation layer 25 from the first coil 26 to the element front surface 20S. The thickness T22 of the resin portion 85 of the encapsulation resin 80 corresponds to the thickness of the encapsulation resin 80 located between the first coil 26 and the second coil 43. The thickness T21 of the element resin portion 25A of the third insulation layer 25 corresponds to the thickness of the element insulation layer 22 located between the first coil 26 and the second coil 43. The sum of the thickness T22 of the encapsulation resin 80 and the thickness T21 of the element insulation layer 22 corresponds to a distance D12 between the first coil 26 and the second coil 43 in the z-direction. The distance D12 between the first coil 26 and the second coil 43 may be, for example, greater than or equal to 50 μm and less than or equal to 100 μm.

### Operation

Operation of the semiconductor device 10 will now be described.

The semiconductor device 10 includes the semiconductor element 20, the second coil 43, and the encapsulation resin 80. The semiconductor element 20 includes the element front surface 20S and the element back surface 20R facing in opposite directions in the z-direction. The semiconductor element 20 further includes the element insulation layer 22 including the insulation front surface 22S defining the element front surface 20S and the first coil 26 disposed in the element insulation layer 22. The second coil 43 is separated from the first coil 26 in the z-direction. The encapsulation resin 80 is in contact with the element insulation layer 22 and encapsulates the semiconductor element 20 and the second coil 43. The first coil 26 and the second coil 43 are located at opposite sides of the element insulation layer 22 and the encapsulation resin 80 and are opposed to each other in the thickness-wise direction.

The breakdown voltage of the semiconductor device 10 is determined by the distance D12 between the first coil 26 and the second coil 43 in the z-direction. The element insulation layer 22 and the encapsulation resin 80 are located between the first coil 26 and the second coil 43. This increases the thickness of the element insulation layer 22 and the encapsulation resin 80 located between the first coil 26 and the second coil 43, thereby improving the breakdown voltage of the semiconductor device 10.

The encapsulation resin 80 is formed by, for example, molding. Thus, the insulation body is readily formed between the first coil 26 and the second coil 43 as compared to when, for example, an insulation body is formed of SiN or SiO₂ through chemical vapor deposition (CVD).

The semiconductor element 20 includes the connection pads 27A and 27B electrically connected to the first coil 26. The connection pads 27A and 27B are electrically connected to the element electrodes 31A and 31B. The element electrodes 31A and 31B are electrically connected to the element connectors 53A and 53B of the conductor 40 by the bonding portions SD. The bonding portion SD is, for example, a solder layer. Thus, the semiconductor element 20 is readily electrically connected to the conductor 40 as compared to when a bonding wire or the like is used.

The semiconductor element 20 includes the first element electrode 31A and the second element electrode 31B electrically connected to the first coil 26. The semiconductor element 20 is arranged so that the element front surface 20S, on which the element electrodes 31A and 31B are arranged, faces the conductor 40 including the second coil 43. Thus, the semiconductor device 10 is readily arranged so that the first coil 26 is opposed to the second coil 43.

The semiconductor device 10 includes the first external connection terminal 51A and the second external connection terminal 51B, which are electrically connected to the first coil 26, and the third external connection terminal 61A and the fourth external connection terminal 61B, which are electrically connected to the second coil 43. The first external connection terminal 51A, the second external connection terminal 51B, the third external connection terminal 61A, and the fourth external connection terminal 61B are exposed from the resin lower surface 80R of the encapsulation resin 80. The semiconductor device 10 is mounted on the substrate 920, which is shown in FIG. 2, via the first external connection terminal 51A, the second external connection terminal 51B, the third external connection terminal 61A, and the fourth external connection terminal 61B, which are exposed from the resin lower surface 80R of the encapsulation resin 80. Thus, the semiconductor device 10 is readily mounted on the substrate 920.

The element electrodes 31A and 31B, which are connected to the first coil 26, are connected to the element connectors 53A and 53B of the conductor 40 by the bonding portions SD. The element electrodes 31C and 31D, which are disconnected from the first coil 26, are connected to the dummy element connectors 53C and 53D of the conductor 40 by the bonding portions SD. The dummy element connectors 53C and 53D are located at the same position as the element connectors 53A and 53B in the z-direction. The element electrodes 31A, 31B, 31C, and 31D of the semiconductor element 20 are located at the same position in the z-direction. The second coil 43 of the conductor 40 is located at the same position as the element connectors 53A and 53B and the dummy element connectors 53C and 53D. This allows the insulation front surface 22S of the element insulation layer 22 of the semiconductor element 20 to be opposed to an upper surface 43S of the second coil 43 in the z-direction. The first coil 26, which is disposed in the element insulation layer 22 of the semiconductor element 20, is opposed to the second coil 43 in the z-direction.

### Advantages

As described above, the first embodiment has the following advantages.

(1-1) The semiconductor device 10 includes the semiconductor element 20, the second coil 43, and the encapsulation resin 80. The semiconductor element 20 includes the element front surface 20S and the element back surface 20R facing in opposite directions in the z-direction. The semiconductor element 20 further includes the element insulation layer 22 including the insulation front surface 22S defining the element front surface 20S and the first coil 26 disposed in the element insulation layer 22. The second coil 43 is separated from the first coil 26 in the z-direction. The encapsulation resin 80 is in contact with the element insulation layer 22 and encapsulates the semiconductor element 20 and the second coil 43. The first coil 26 and the second coil 43 are located at opposite sides of the element insulation layer 22 and the encapsulation resin 80 and are opposed to each other in the thickness-wise direction.

The breakdown voltage of the semiconductor device 10 is determined by the distance D12 between the first coil 26 and the second coil 43 in the z-direction. The element insulation layer 22 and the encapsulation resin 80 are located between the first coil 26 and the second coil 43. This increases the thickness of the element insulation layer 22 and the encapsulation resin 80 located between the first coil 26 and the second coil 43, thereby improving the breakdown voltage of the semiconductor device 10.

(1-2) The encapsulation resin 80 is formed by, for example, molding. Thus, the insulation body is readily formed between the first coil 26 and the second coil 43 as compared to when, for example, an insulation body is formed of SiN or SiO₂ through chemical vapor deposition (CVD).

(1-3) The semiconductor element 20 includes the connection pads 27A and 27B electrically connected to the first coil 26. The connection pads 27A and 27B are electrically connected to the element electrodes 31A and 31B. The element electrodes 31A and 31B are electrically connected to the element connectors 53A and 53B of the conductor 40 by the bonding portions SD. The bonding portion SD is, for example, a solder layer. Thus, the semiconductor element 20 is readily electrically connected to the conductor 40 as compared to when a bonding wire or the like is used.

(1-4) The semiconductor element 20 includes the first element electrode 31A and the second element electrode 31B electrically connected to the first coil 26. The semiconductor element 20 is arranged so that the element front surface 20S, on which the element electrodes 31A and 31B are arranged, faces the conductor 40 including the second coil 43. Thus, the semiconductor device 10 is readily arranged so that the first coil 26 is opposed to the second coil 43.

(1-5) The semiconductor device 10 includes the first external connection terminal 51A and the second external connection terminal 51B, which are electrically connected to the first coil 26, and the third external connection terminal 61A and the fourth external connection terminal 61B, which are electrically connected to the second coil 43. The first external connection terminal 51A, the second external connection terminal 51B, the third external connection terminal 61A, and the fourth external connection terminal 61B are exposed from the resin lower surface 80R of the encapsulation resin 80. The semiconductor device 10 is mounted on the substrate 920 of the signal transmission device 900 via the first external connection terminal 51A, the second external connection terminal 51B, the third external connection terminal 61A, and the fourth external connection terminal 61B, which are exposed from the resin lower surface 80R of the encapsulation resin 80. Thus, the semiconductor device 10 is readily mounted on the substrate 920.

(1-6) The element electrodes 31A and 31B, which are connected to the first coil 26, are connected to the element connectors 53A and 53B of the conductor 40 by the bonding portions SD. The element electrodes 31C and 31D, which are disconnected from the first coil 26, are connected to the dummy element connectors 53C and 53D of the conductor 40 by the bonding portions SD. The dummy element connectors 53C and 53D are located at the same position as the element connectors 53A and 53B in the z-direction. The element electrodes 31A, 31B, 31C, and 31D of the semiconductor element 20 are located at the same position in the z-direction. The second coil 43 of the conductor 40 is located at the same position as the element connectors 53A and 53B and the dummy element connectors 53C and 53D. This allows the insulation front surface 22S of the element insulation layer 22 of the semiconductor element 20 to be opposed to the upper surface 43S of the second coil 43 in the z-direction. The first coil 26, which is disposed in the element insulation layer 22 of the semiconductor element 20, is opposed to the second coil 43 in the z-direction.

### Modified Example of First Embodiment

A semiconductor device in a modified example of the first embodiment will now be described. In the semiconductor device of the modified example, the same reference characters are given to those components that are the same as the corresponding components of the first embodiment. Such components will not be described in detail.

The surfaces of the external connection terminals 51A, 51B, and 61A exposed from the encapsulation resin 80 may be covered by an external conductive film. The external conductive film is formed of, for example, a stack of metal layers. The metal layers include, for example, a Ni layer, a Pd layer, and a Au layer. The material of the external conductive film is not limited. For example, the external conductive film may be formed by stacking a Ni layer and a Au layer or may be formed of Sn.

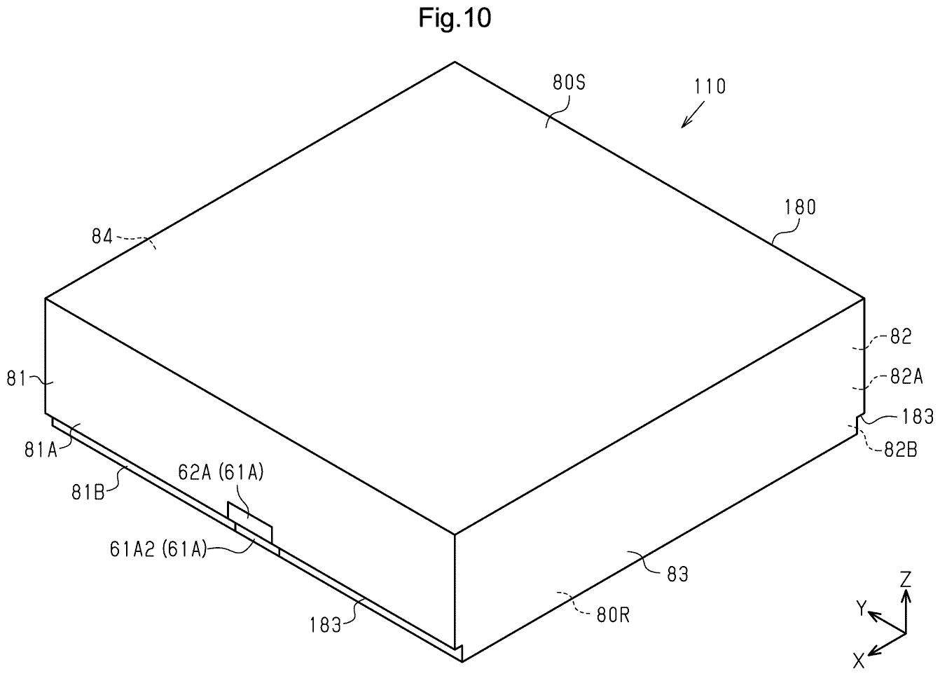

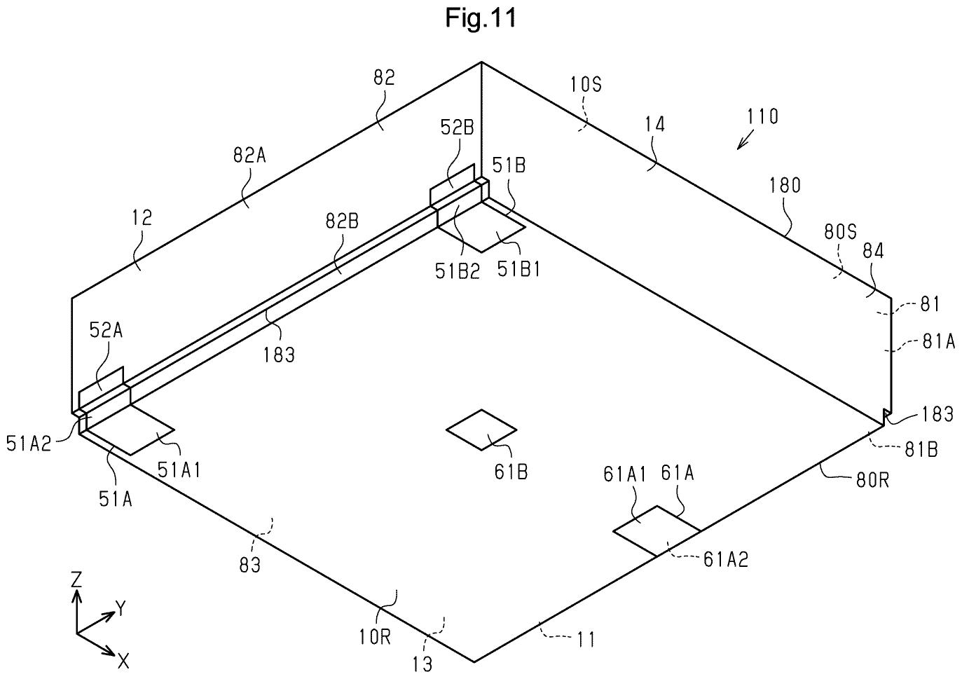

As shown in FIGS. 10 and 11, a semiconductor device 110 includes an encapsulation resin 180. The resin side surfaces 81 and 82 of the encapsulation resin 180 include first side surfaces 81A and 82A and second side surfaces 81B and 82B. The first side surfaces 81A and 82A are located closer to the resin upper surface 80S than to the resin lower surface 80R in the z-direction. The second side surfaces 81B and 82B are located closer to the resin lower surface 80R than to the resin upper surface 80S in the z-direction. The second side surfaces 81B and 82B are located inward of the encapsulation resin 180 with respect to the first side surfaces 81A and 82A in plan view. In other words, in the z-direction, the encapsulation resin is greater in size at the side of the resin upper surface 80S than at the side of the resin lower surface 80R.

The first side surfaces 81A and 82A are orthogonal to the resin upper surface 80S. The second side surfaces 81B and 82B are orthogonal to the resin lower surface 80R. The encapsulation resin 180 includes a step 183 recessed inward of the encapsulation resin 180 at the first side surfaces 81A and 82A and the second side surfaces 81B and 82B of the resin side surfaces 81 and 82 in plan view. The step 183 may be disposed in the resin side surfaces 81 to 84.

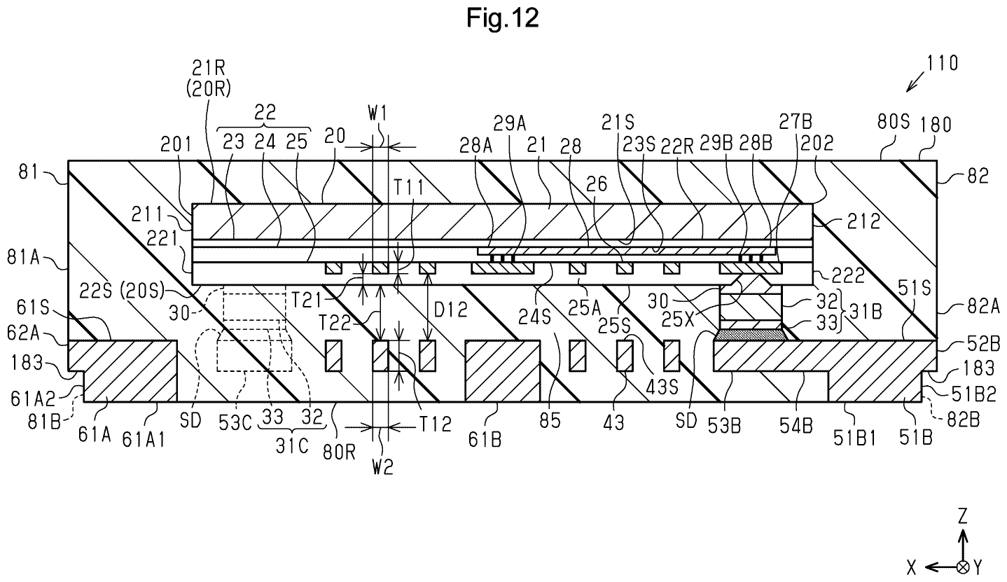

As shown in FIGS. 10 to 12, the first external connection terminal 51A is exposed from the second side surface 82B of the resin side surface 82 in the x-direction. That is, the first external connection terminal 51A is exposed in the resin lower surface 80R of the encapsulation resin 180 and the second side surface 82B of the resin side surface 82. The first external connection terminal 51A includes a lower surface 51A1 and a side surface 51A2 exposed from the encapsulation resin 180. The lower surface 51A1 and the side surface 51A2 of the first external connection terminal 51A may be covered by an external conductive film.

The second external connection terminal 51B is exposed from the second side surface 82B of the resin side surface 82 in the x-direction. That is, the second external connection terminal 51B is exposed in the resin lower surface 80R of the encapsulation resin 180 and the second side surface 82B of the resin side surface 82. The second external connection terminal 51B includes a lower surface 51B1 and a side surface 51B2 exposed from the encapsulation resin 180. The lower surface 51B1 and the side surface 51B2 of the second external connection terminal 51B are covered by an external conductive film.

The third external connection terminal 61A is exposed from the second side surface 81B of the resin side surface 81 in the x-direction. That is, the third external connection terminal 61A is exposed in the resin lower surface 80R of the encapsulation resin 180 and the second side surface 81B of the resin side surface 81. The third external connection terminal 61A includes a lower surface 61A1 and a side surface 61A2 exposed from the encapsulation resin 180. The lower surface 61A1 and the side surface 61A2 of the third external connection terminal 61A are covered by an external conductive film.

The semiconductor device 110 of the modified example is mounted on the substrate 920 shown in FIG. 2. In this case, when the external connection terminals 51A, 51B, 61A, and 61B are connected to mount pads of the substrate 920 by solder, the solder adheres to the lower surfaces 51A1, 51B1, and 61A1 and the side surfaces 51A2, 51B2, and 61A2 of the external connection terminals 51A, 51B, and 61A. For example, in a reflow process, solder is in a liquid state and flows upward on the side surfaces 51A2, 51B2, and 61A2 of the external connection terminals 51A, 51B, and 61A to form a fillet between the side surfaces 51A2, 51B2, and 61A2 and the mount pads. Thus, the semiconductor device 110 facilitates formation of a solder fillet. The solder fillet increases the area bonded by solder, thereby increasing the connection strength. In addition, the soldering state of the semiconductor device 110 is readily checked based on the solder fillet.

### Second Embodiment

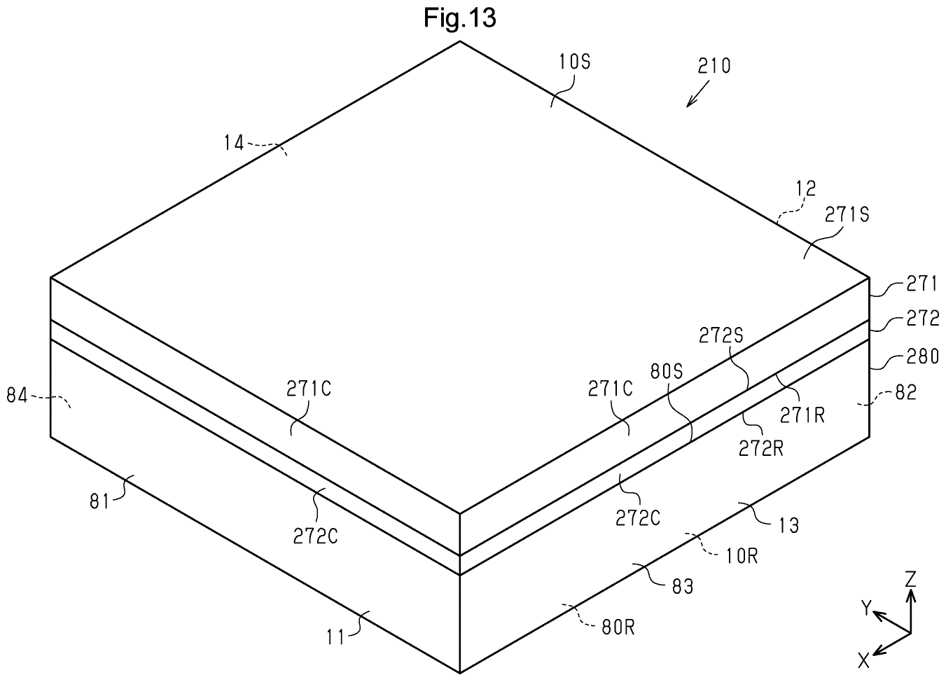

A second embodiment of a semiconductor device 210 will now be described with reference to FIGS. 13 to 18. In lieu of the semiconductor device 10 shown in FIG. 2, the semiconductor device 210 is mounted on the substrate 920. The semiconductor device 210 of the second embodiment differs from the semiconductor device 10 of the first embodiment in the structure of a conductor 240 connected to the semiconductor element 20. In the description below, the same reference characters are given to those components that are the same as the corresponding components of the first embodiment. Such components will not be described in detail.

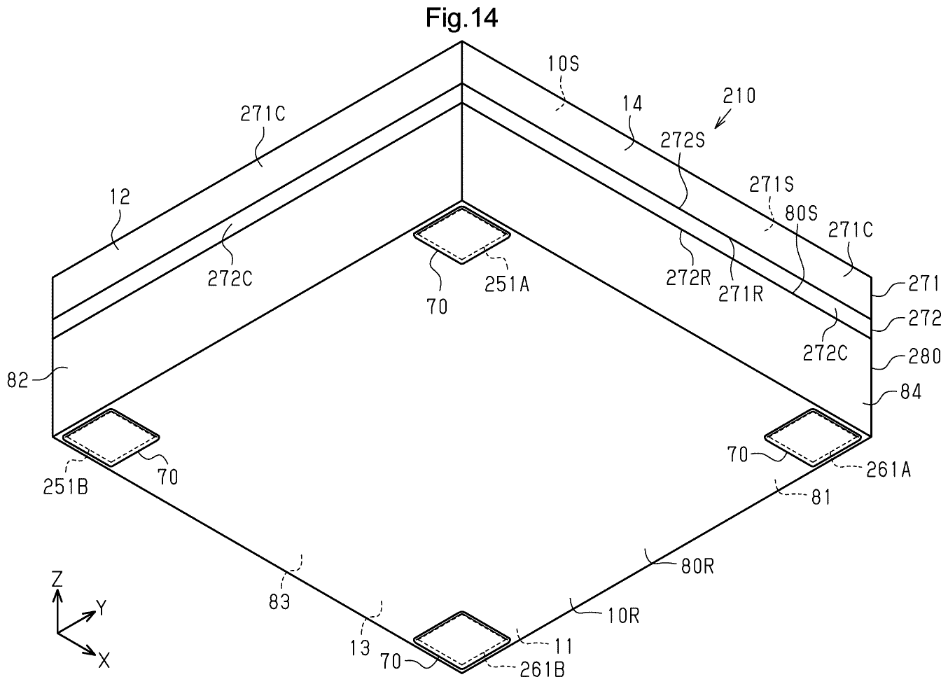

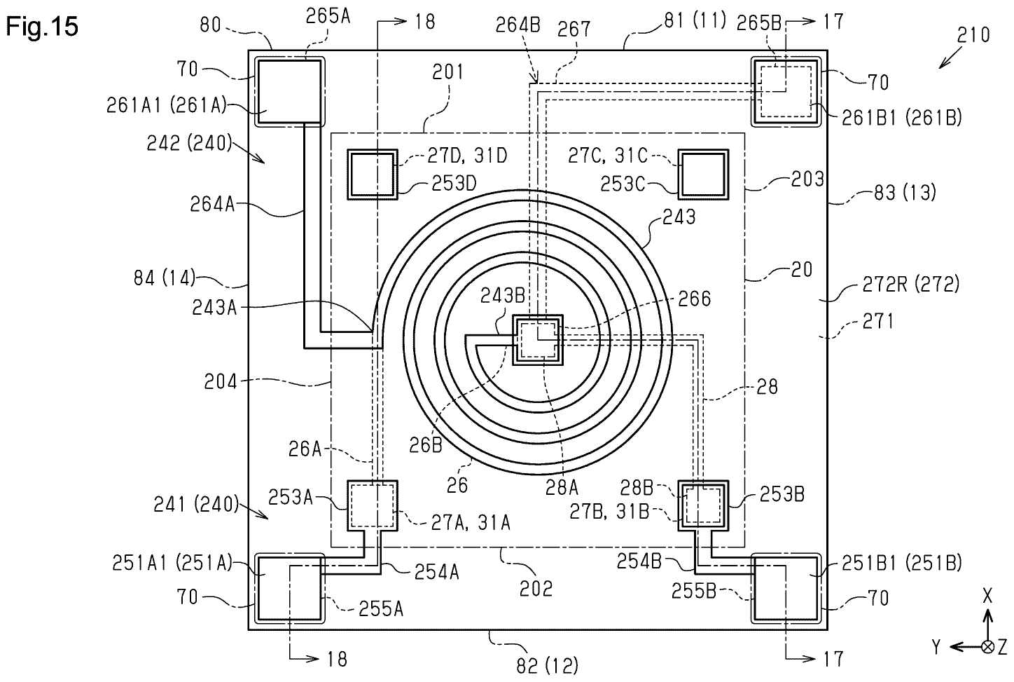

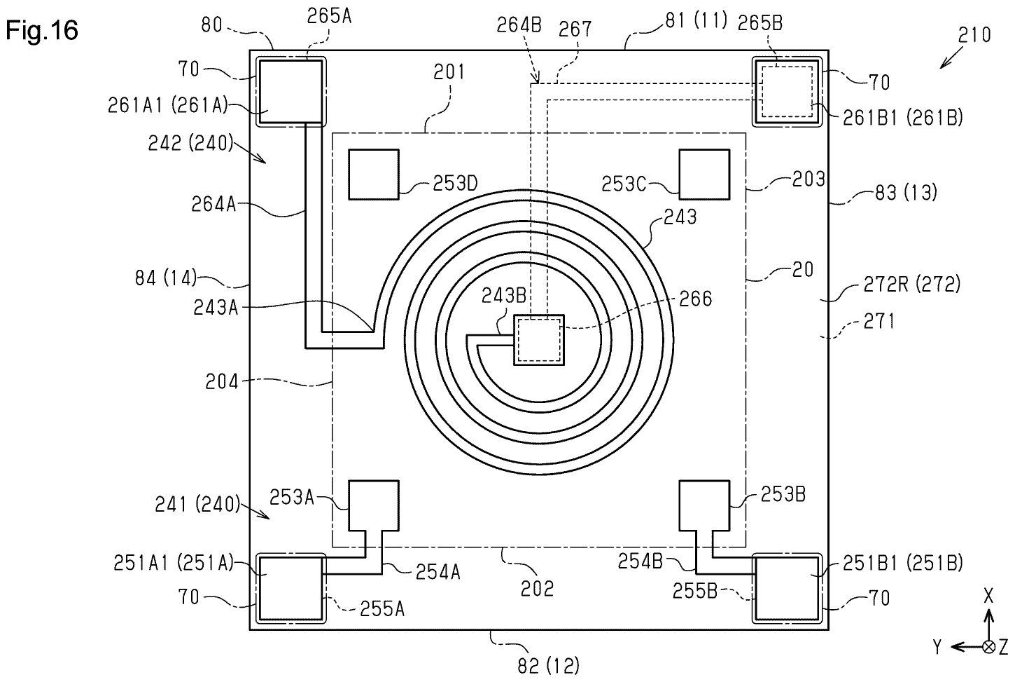

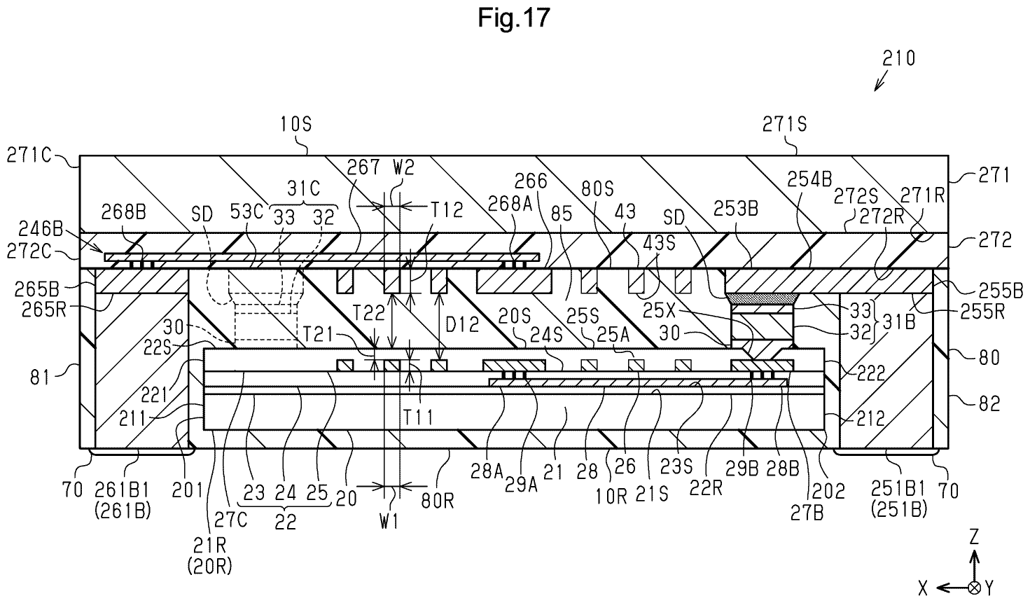

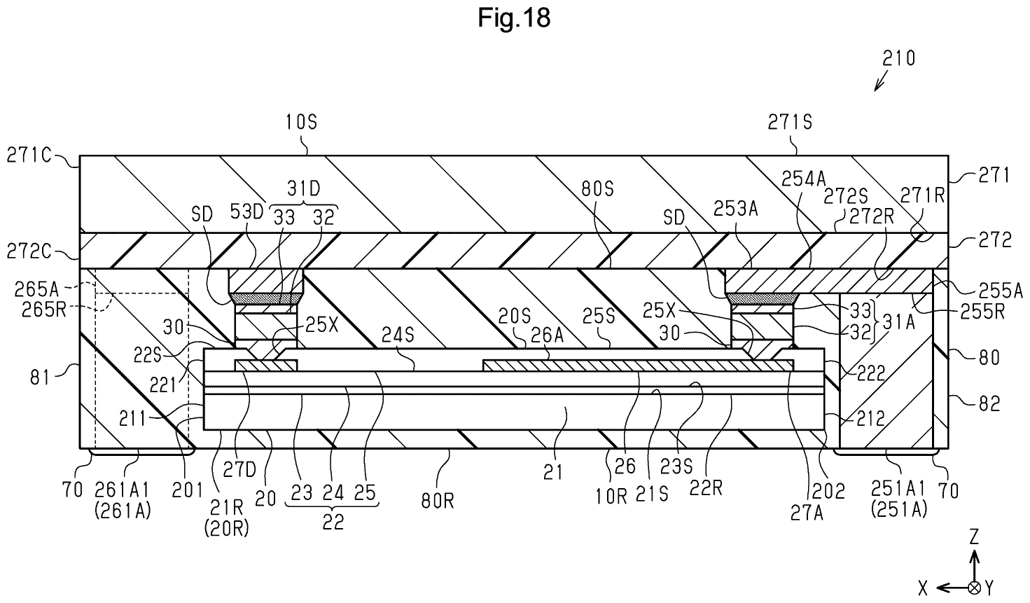

FIGS. 13 and 14 are perspective views showing the exterior of the semiconductor device 210. FIG. 13 is an upper perspective view of the semiconductor device 210, and FIG. 14 is a lower perspective view of the semiconductor device 210. FIG. 15 is a plan view showing the lower side of the semiconductor device 210. In FIG. 15, an encapsulation resin 280 is shown transparently. FIG. 16 is a plan view of the conductor 240. FIG. 17 is a schematic cross-sectional view of the semiconductor device 210 taken along line 17-17 in FIG. 15. FIG. 18 is a schematic cross-sectional view of the semiconductor device 210 taken along line 18-18 in FIG. 15. For the sake of convenience, FIGS. 17 and 18 may show a member that is not present on the line indicating the cross-sectional position. Further, the position and size of a member may differ from those shown in FIGS. 15 and 16.

### General Structure of Semiconductor Device

As shown in FIGS. 13 and 14, the semiconductor device 210 is, for example, rectangular-box-shaped.

As shown in FIGS. 13 to 18, the semiconductor device 210 includes a substrate 271, a substrate insulation film 272, the semiconductor element 20, the conductor 240, and the encapsulation resin 280.

The conductor 240 includes a second coil 243 and external connection terminals 251A, 251B, 261A, and 261B. The semiconductor element 20 is mounted on the conductor 240. The first coil 26 of the semiconductor element 20 is opposed to the second coil 243 of the conductor 240 in the z-direction. The first coil 26 and the second coil 243 correspond to the coils 913A and 913B shown in FIG. 1. As shown in FIGS. 17 and 18, the semiconductor device 210 includes an external conductive film 70 covering the external connection terminals 251A, 251B, 261A, and 261B.

The semiconductor device 210 includes a device upper surface 10S, a device lower surface 10R, and device side surfaces 11, 12, 13, and 14.

### Substrate

The substrate 271 has the form of, for example, a rectangular plate. The substrate 271 may be insulating. The substrate 271 may be, for example, a semiconductor substrate. The substrate 271 is formed from, for example, a material including Si.

The substrate 271 includes an upper surface 271S, a lower surface 271R, and side surfaces 271C. The upper surface 271S and the lower surface 271R face in opposite directions in the z-direction. The side surfaces 271C intersect the upper surface 271S and the lower surface 271R. The side surfaces 271C face in one of the x-direction and the y-direction. The upper surface 271S of the substrate 271 defines the device upper surface 10S of the semiconductor device 210. The side surfaces 271C define the device side surfaces 11 to 14 of the semiconductor device 210.

The substrate insulation film 272 is disposed on the lower surface 271R of the substrate 271. The substrate insulation film 272 and the substrate 271 are the same in size in plan view.

The substrate insulation film 272 includes an upper surface 272S, a lower surface 272R, and side surfaces 272C. The upper surface 272S and the lower surface 272R face in opposite directions in the z-direction. The side surfaces 272C intersect the upper surface 272S and the lower surface 272R. The side surfaces 272C face in one of the x-direction and the y-direction. The upper surface 272S of the substrate insulation film 272 is in contact with the lower surface 272R of the substrate 271. The side surfaces 272C define the device side surfaces 11 to 14 of the semiconductor device 210.

The substrate insulation film 272 is formed from, for example, a material including Si. The substrate insulation film 272 is formed of SiO₂, SiN, or the like. The substrate insulation film 272 may be formed of multiple insulation films.

### Encapsulation Resin

The encapsulation resin 280 is disposed on the lower surface 272R of the substrate insulation film 272. In plan view, the encapsulation resin 280 is the same in size as the substrate 271 and the substrate insulation film 272.

The encapsulation resin 280 includes a resin upper surface 80S, a resin lower surface 80R, and resin side surfaces 81 to 84. The resin upper surface 80S of the encapsulation resin 280 is in contact with the lower surface 272R of the substrate insulation film 272. That is, the semiconductor device 210 includes the substrate 271 and the substrate insulation film 272 and the encapsulation resin 280, which are stacked on the lower surface 271R of the substrate 271.

The encapsulation resin 280 encapsulates the semiconductor element 20, the conductor 240, and the bonding portion SD. The encapsulation resin 280 covers the element front surface 20S, the element back surface 20R, and the element side surfaces 201 to 204 of the semiconductor element 20. Thus, the semiconductor element 20 is embedded in the encapsulation resin 280. The semiconductor element 20 is arranged in the encapsulation resin 280 so that the element front surface 20S and the resin upper surface 80S of the encapsulation resin 280 face in the same direction. Thus, the element front surface 20S of the semiconductor element 20 is opposed to the lower surface 272R of the substrate insulation film 272.

The encapsulation resin 280 is formed from, for example, an electrically insulating resin. The resin may be, for example, a synthetic resin of which the base component is an epoxy resin. The encapsulation resin 280 may be formed from, for example, a synthetic resin including a filler. The filler is formed from, for example, SiO₂. The encapsulation resin 280 is, for example, colored black. The material properties and shape of the encapsulation resin 280 are not limited.

### Conductor

As shown in FIGS. 15 to 17, the conductor 240 includes a first wiring member 241, a second wiring member 242, and the second coil 243. The conductor 240 may be formed from, for example, a plating layer. The conductor 240 is formed from a material including, for example, Cu.

### First Wiring Member

The first wiring member 241 includes a first external connection terminal 251A, a second external connection terminal 251B, a first element connector 253A, a second element connector 253B, a first interconnect 254A, a second interconnect 254B, a first terminal connector 255A, and a second terminal connector 255B. The first element connector 253A, the second element connector 253B, the first interconnect 254A, the second interconnect 254B, the first terminal connector 255A, and the second terminal connector 255B form a first lead wire.

As shown in FIGS. 15 and 18, the first element connector 253A, the first interconnect 254A, and the first terminal connector 255A are formed on the lower surface 272R of the substrate insulation film 272. The first element connector 253A is electrically connected to the first terminal connector 255A by the first interconnect 254A. The first element connector 253A, the first interconnect 254A, and the first terminal connector 255A may be formed integrally as a single body.

As shown in FIGS. 15 and 17, the second element connector 253B, the second interconnect 254B, and the second terminal connector 255B are formed on the lower surface 272R of the substrate insulation film 272. The second element connector 253B is electrically connected to the second terminal connector 255B by the second interconnect 254B. The second element connector 253B, the second interconnect 254B, and the second terminal connector 255B may be formed integrally as a single body.

As shown in FIG. 15, the first element connector 253A and the second element connector 253B overlap the semiconductor element 20 in plan view. The first element connector 253A and the second element connector 253B overlap the element electrodes 31A and 31B of the semiconductor element 20 in the z-direction.

The first element connector 253A and the second element connector 253B are quadrilateral in plan view. The shape of the first element connector 253A and the second element connector 253B may be changed in any manner and may be, for example, circular or polygonal in plan view.

As shown in FIG. 18, the first element connector 253A is electrically connected to the first element electrode 31A of the semiconductor element 20 by the bonding portion SD.

As shown in FIG. 17, the second element connector 253B is electrically connected to the second element electrode 31B of the semiconductor element 20 by the bonding portion SD.

As shown in FIG. 18, the first external connection terminal 251A is disposed on a lower surface 255R of the first terminal connector 255A. The first external connection terminal 251A is electrically connected to the first terminal connector 255A. The first external connection terminal 251A extends from the first terminal connector 255A toward the resin lower surface 80R of the encapsulation resin 280. The first external connection terminal 251A includes a lower surface 251A1 exposed from the resin lower surface 80R of the encapsulation resin 280.

As shown in FIG. 17, the second external connection terminal 251B is disposed on the lower surface 255R of the second terminal connector 255B. The second external connection terminal 251B is electrically connected to the second terminal connector 255B. The second external connection terminal 251B extends from the second terminal connector 255B toward the resin lower surface 80R of the encapsulation resin 280. The second external connection terminal 251B includes a lower surface 251B1 exposed from the resin lower surface 80R of the encapsulation resin 280.

As shown in FIGS. 15 and 16, the first external connection terminal 251A and the second external connection terminal 251B are quadrilateral in plan view. The shape of the first external connection terminal 251A and the second external connection terminal 251B may be changed in any manner and may be, for example, circular or polygonal in plan view.

As shown in FIGS. 15 and 16, in an example, the first external connection terminal 251A and the second external connection terminal 251B are arranged along the device side surface 12 of the semiconductor device 210. The first external connection terminal 251A and the second external connection terminal 251B may be separated in the y-direction. The first external connection terminal 251A and the second external connection terminal 251B are arranged in the y-direction in plan view. The first external connection terminal 251A is located at the corner formed of the device side surface 12 and the device side surface 14 of the semiconductor device 210. The second external connection terminal 251B is located at the corner of the device side surface 12 and the device side surface 13 of the semiconductor device 210.

### Second Coil

As shown in FIG. 17, the second coil 243 is formed on the lower surface 272R of the substrate insulation film 272. As shown in FIGS. 15 and 16, the second coil 243 is spiral in plan view. As shown in FIG. 15, in plan view, the second coil 243 overlaps the first coil 26 of the semiconductor element 20.

### Second Wiring Member

As shown in FIGS. 15 to 18, the second wiring member 242 includes a third external connection terminal 261A, a fourth external connection terminal 261B, a third interconnect 264A, a fourth interconnect 264B, a third terminal connector 265A, a fourth terminal connector 265B, and an end connector 266. The third interconnect 264A, the fourth interconnect 264B, the third terminal connector 265A, and the fourth terminal connector 265B form a “second lead wire.”

As shown in FIGS. 15 and 16, the second coil 243 is spiral in plan view. The second coil 243 includes a first end 243A located outward and a second end 243B located inward. The first end 243A corresponds to an “outer end.” The second end 243B corresponds to an “inner end.”

The end connector 266 is arranged at an inner side of the second coil 243. The end connector 266 is electrically connected to the second end 243B of the second coil 243. The first end 243A of the second coil 243 is electrically connected to the third terminal connector 265A by the third interconnect 264A. The second coil 243, the end connector 266, the third interconnect 264A, and the third terminal connector 265A may be formed integrally as a single body.

As shown in FIGS. 15 to 17, the end connector 266 is electrically connected to the fourth terminal connector 265B by the fourth interconnect 264B. As shown in FIG. 17, the fourth interconnect 264B is embedded in the substrate insulation film 272. The fourth interconnect 264B includes an embedded wire 267 and vias 268A and 268B. The embedded wire 267 includes a first end electrically connected to the end connector 266 by the via 268A. The embedded wire 267 includes a second end electrically connected to the fourth terminal connector 265B by the via 268B.

As shown in FIG. 18, the third external connection terminal 261A is disposed on a lower surface 265R of the third terminal connector 265A. The third external connection terminal 261A is electrically connected to the third terminal connector 265A. The third external connection terminal 261A extends from the third terminal connector 265A toward the resin lower surface 80R of the encapsulation resin 280. The third external connection terminal 261A includes a lower surface 261A1 exposed from the encapsulation resin 280.

As shown in FIG. 17, the fourth external connection terminal 261B is disposed on the lower surface 265R of the fourth terminal connector 265B. The fourth external connection terminal 261B is electrically connected to the fourth terminal connector 265B. The fourth external connection terminal 261B extends from the fourth terminal connector 265B toward the resin lower surface 80R of the encapsulation resin 280. The fourth external connection terminal 261B includes a lower surface 261B1 exposed from the encapsulation resin 280.

As shown in FIGS. 15 and 16, the third and fourth external connection terminals 261A and 261B are quadrilateral in plan view. The shape of the third and fourth external connection terminals 261A and 261B may be changed in any manner and may be, for example, circular or polygonal in plan view.

In an example, the third external connection terminal 261A and the fourth external connection terminal 261B are arranged along the device side surface 11 of the semiconductor device 210. The third external connection terminal 261A and the fourth external connection terminal 261B may be separated in the y-direction. The first external connection terminal 251A and the second external connection terminal 251B are arranged in the y-direction in plan view. The third external connection terminal 261A is located at the corner of the device side surface 11 and the device side surface 14 of the semiconductor device 210. The fourth external connection terminal 261B is located at the corner of the device side surface 11 and the device side surface 13 of the semiconductor device 210.

### External Conductive Film

As shown in FIGS. 15 to 18, the external conductive film 70 includes the lower surfaces 251A1, 251B1, 261A1, and 261B1 of the external connection terminals 251A, 251B, 261A, and 261B. The external conductive film 70 is formed of, for example, a stack of metal layers. The metal layers include, for example, a Ni layer, a Pd layer, and a Au layer. The material of the external conductive film is not limited. For example, the external conductive film may be formed by stacking a Ni layer and a Au layer or may be formed of Sn.

### Advantages

As described above, the second embodiment has the following advantages.

(2-1) The same advantages as those of the semiconductor device 10 of the first embodiment are obtained.

(2-2) The conductor 240 is formed from, for example, a plating layer. The semiconductor device 210 may be reduced in size as compared to the semiconductor device 10 in which the conductor 40 is formed of the lead frame.

### Modified Examples of Second Embodiment

A semiconductor device in a modified example of the second embodiment will now be described. In the semiconductor device of the modified example, the same reference characters are given to those components that are the same as the corresponding components of the second embodiment. Such components will not be described in detail.

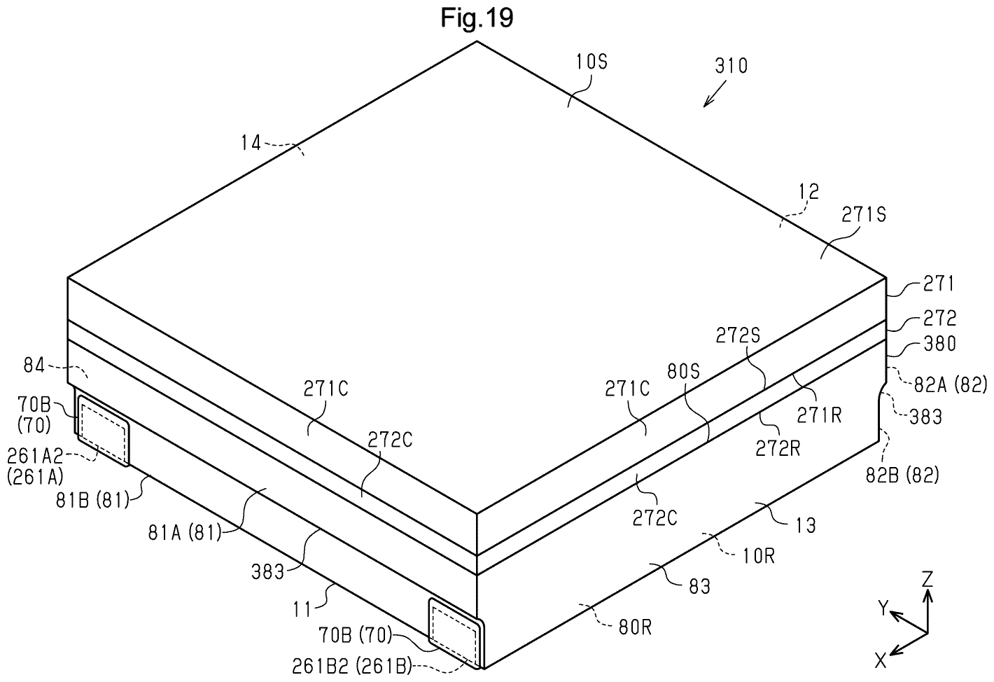

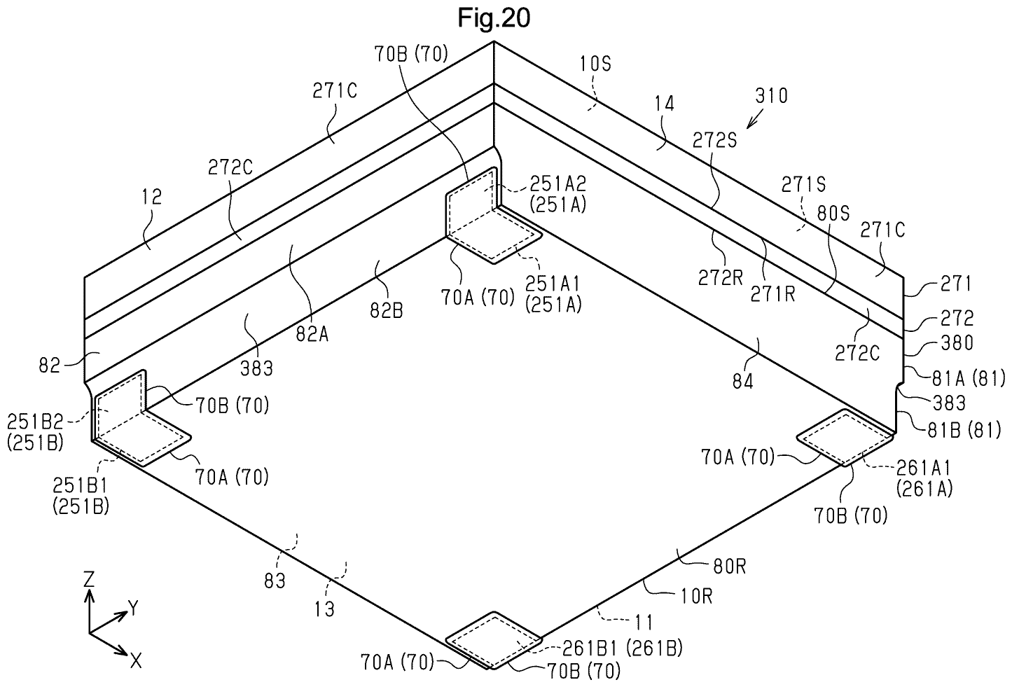

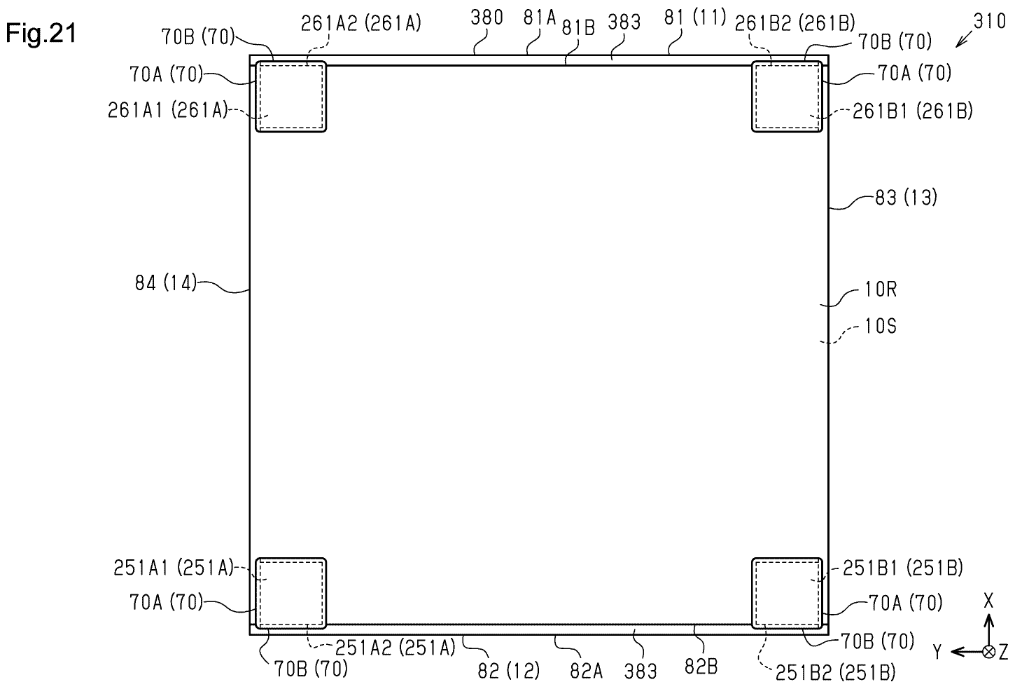

As shown in FIGS. 19 to 21, a semiconductor device 310 includes an encapsulation resin 380. The resin side surfaces 81 and 82 of the encapsulation resin 380 include the first side surfaces 81A and 82A and the second side surfaces 81B and 82B. The first side surfaces 81A and 82A are located closer to the resin upper surface 80S than to the resin lower surface 80R in the z-direction. The second side surfaces 81B and 82B are located closer to the resin lower surface 80R than to the resin upper surface 80S in the z-direction. The second side surfaces 81B and 82B of the resin side surfaces 81 and 82 are located inward of the encapsulation resin 380 with respect to the first side surfaces 81A and 82A of the resin side surfaces 81 and 82. In other words, in the z-direction, the encapsulation resin is greater in size at the side of the resin upper surface 80S than at the side of the resin lower surface 80R.

The first side surfaces 81A and 82A of the resin side surfaces 81 and 82 are orthogonal to the resin upper surface 80S. The second side surfaces 81B and 82B of the resin side surfaces 81 and 82 are orthogonal to the resin lower surface 80R. The encapsulation resin 380 includes a step 383 recessed inward of the encapsulation resin 380 at the first side surfaces 81A and 82A and the second side surfaces 81B and 82B of the resin side surfaces 81 and 82 in plan view.

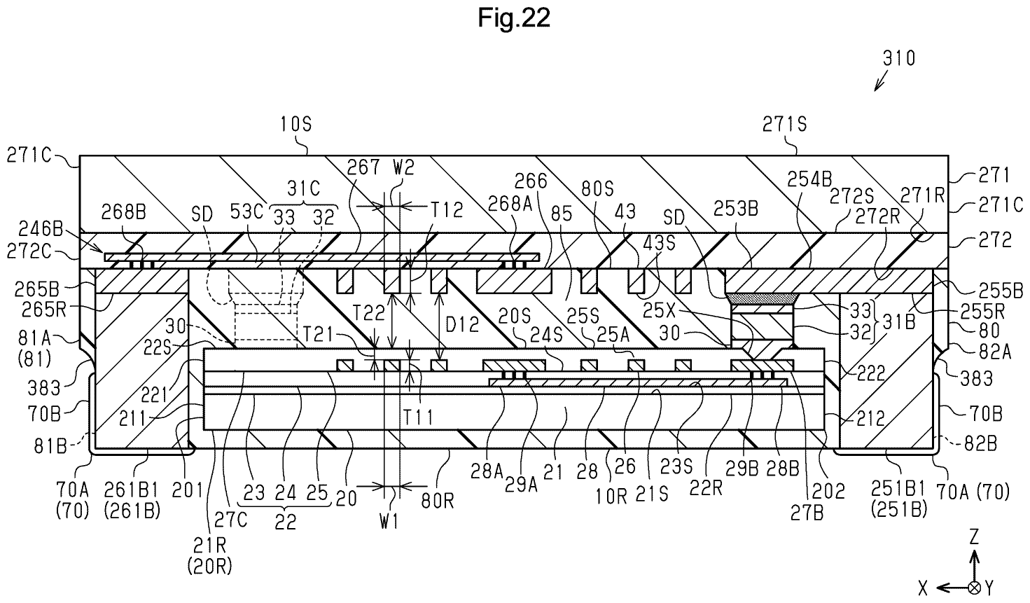

As shown in FIGS. 19 to 22, the first external connection terminal 251A is exposed from the second side surface 82B of the resin side surface 82 in the x-direction. That is, the first external connection terminal 251A is exposed in the resin lower surface 80R of the encapsulation resin 380 and the second side surface 82B of the resin side surface 82. The first external connection terminal 251A includes a lower surface 251A1 and a side surface 251A2 exposed from the encapsulation resin 380. The lower surface 251A1 and the side surface 251A2 of the first external connection terminal 251A are covered by the external conductive film 70. The external conductive film 70 includes the first conductive film 70A, which covers the lower surface 251A1 of the first external connection terminal 251A, and the second conductive film 70B, which covers the side surface 251A2 of the first external connection terminal 251A.

The second external connection terminal 251B is exposed from the second side surface 82B of the resin side surface 82 in the x-direction. That is, the second external connection terminal 251B is exposed in the resin lower surface 80R of the encapsulation resin 380 and the second side surface 82B of the resin side surface 82. The second external connection terminal 251B includes a lower surface 251B1 and a side surface 251B2 exposed from the encapsulation resin 380. The lower surface 251B1 and the side surface 251B2 of the second external connection terminal 251B are covered by the external conductive film 70. The external conductive film 70 includes the first conductive film 70A, which covers the lower surface 251B1 of the second external connection terminal 251B, and the second conductive film 70B, which covers the side surface 251B2 of the first external connection terminal 251A.

The third external connection terminal 261A is exposed from the second side surface 81B of the resin side surface 81 in the x-direction. That is, the third external connection terminal 261A is exposed in the resin lower surface 80R of the encapsulation resin 380 and the second side surface 81B of the resin side surface 81. The third external connection terminal 261A includes the lower surface 261A1 and the side surface 261A2 exposed from the encapsulation resin 380. The lower surface 261A1 and the lower surface 261A2 of the third external connection terminal 261A are covered by the external conductive film 70. The external conductive film 70 includes the first conductive film 70A, which covers the lower surface 261A1 of the third external connection terminal 261A, and the second conductive film 70B, which covers the side surface 261A2 of the first external connection terminal 251A.

The fourth external connection terminal 261B is exposed from the second side surface 81B of the resin side surface 81 in the x-direction. That is, the fourth external connection terminal 261B is exposed in the resin lower surface 80R of the encapsulation resin 380 and the second side surface 81B of the resin side surface 81. The fourth external connection terminal 261B includes the lower surface 261A1 and the side surface 261A2 exposed from the encapsulation resin 380. The lower surface 261B1 and the side surface 261B2 of the fourth external connection terminal 261B are covered by the external conductive film 70. The external conductive film 70 includes the first conductive film 70A, which covers the lower surface 261B1 of the fourth external connection terminal 261B, and the second conductive film 70B, which covers the lower surface 261B2 of the first external connection terminal 251A.

The semiconductor device 310 of the modified example is mounted on the substrate 920 shown in FIG. 2. In this case, when the external connection terminals 251A, 251B, 261A, and 261B are connected to mount pads of the substrate 920 by solder, the solder adheres to the first conductive film 70A and the second conductive film 70B covering the external conductive film 70. More specifically, for example, in a reflow process, solder is in a liquid state and flows upward on the second conductive film 70B to form a fillet between the second conductive film 70B and the mount pads. Thus, the semiconductor device 310 facilitates formation of a solder fillet. The solder fillet increases the area bonded by solder, thereby increasing the connection strength. In addition, the soldering state of the semiconductor device 310 is readily checked based on the solder fillet.

The step 383 may be disposed in each of the resin side surfaces 81 to 84. The step of the resin side surfaces 81 to 84 may be defined by the second side surface, and the external connection terminal may be exposed from the second side surface. The side surface of the external connection terminal exposed from the second surface may be covered by an external conductive film.

### Third Embodiment

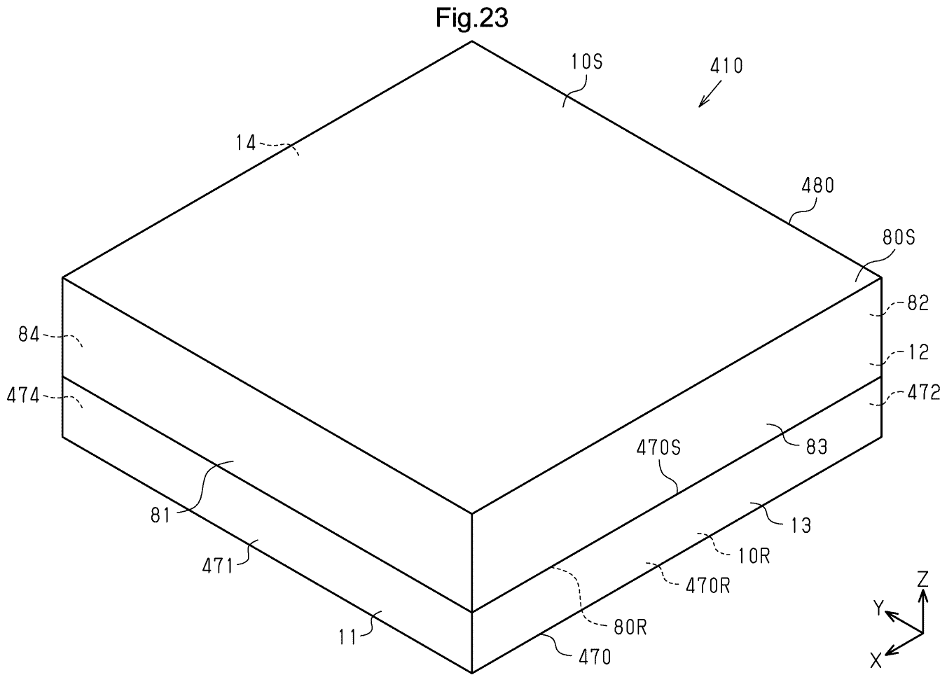

A third embodiment of a semiconductor device 410 will now be described with reference to FIGS. 23 to 28. In lieu of the semiconductor device 10 shown in FIG. 2, the semiconductor device 410 is mounted on the substrate 920. The semiconductor device 410 of the third embodiment differs from the semiconductor devices 10 and 210 in the structure of a conductor 440 connected to the semiconductor element 20. In the description below, the same reference characters are given to those components that are the same as the corresponding components of the first and second embodiments. Such components will not be described in detail.

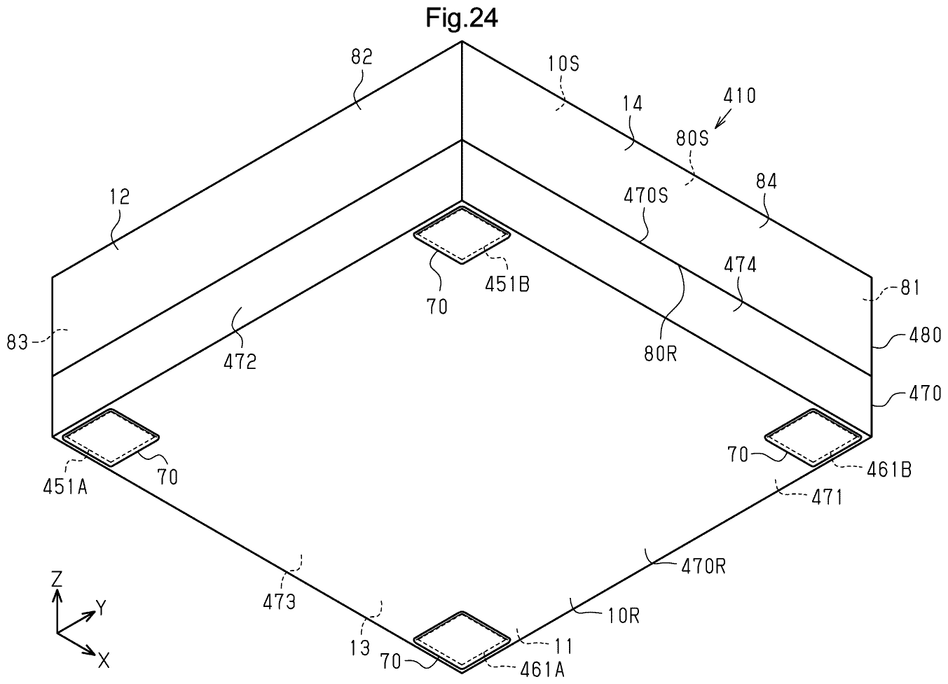

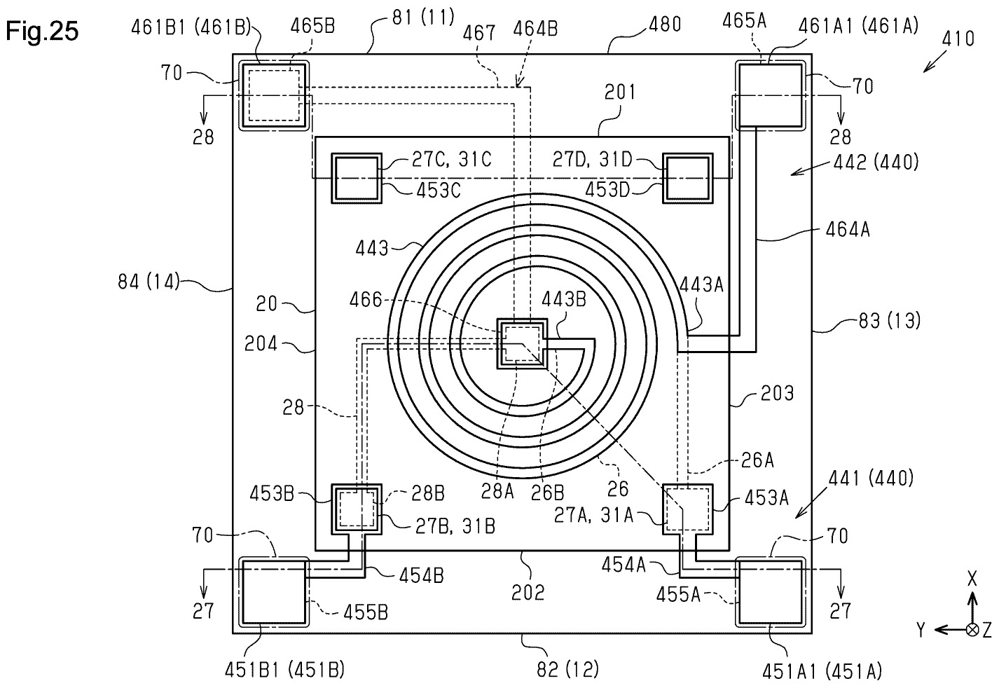

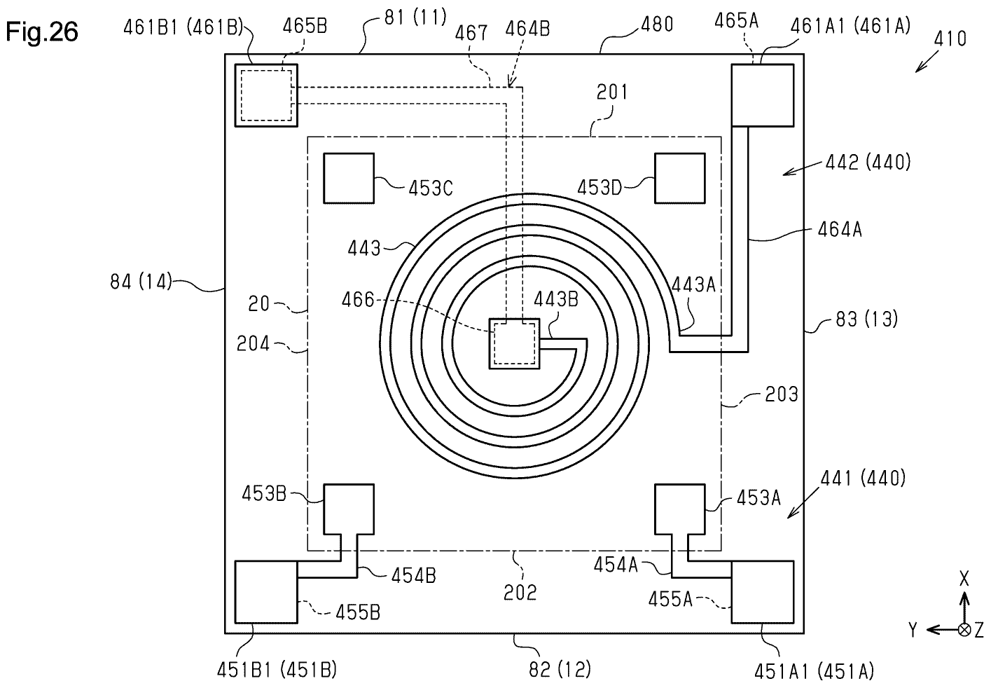

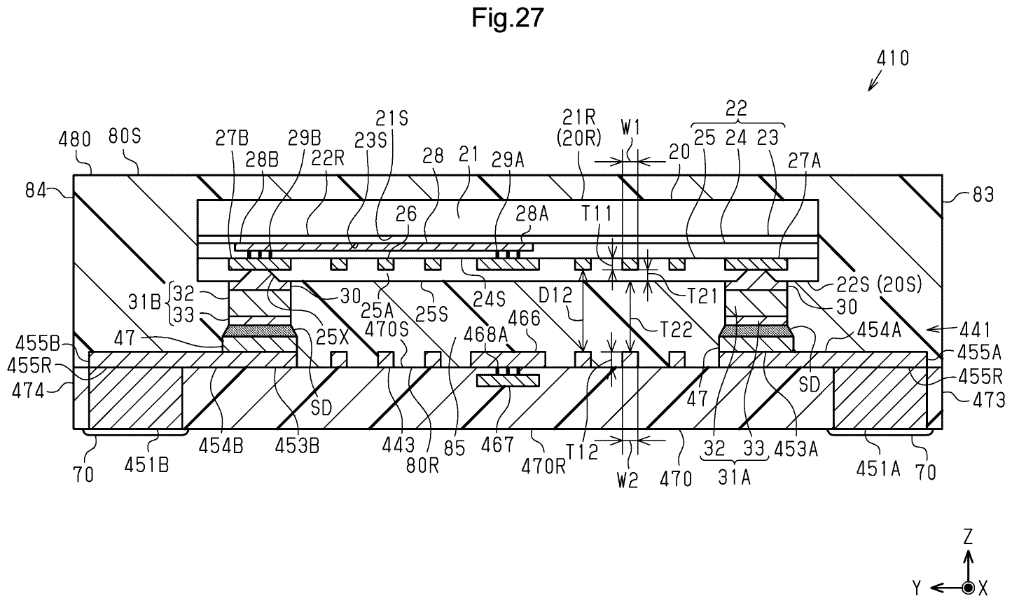

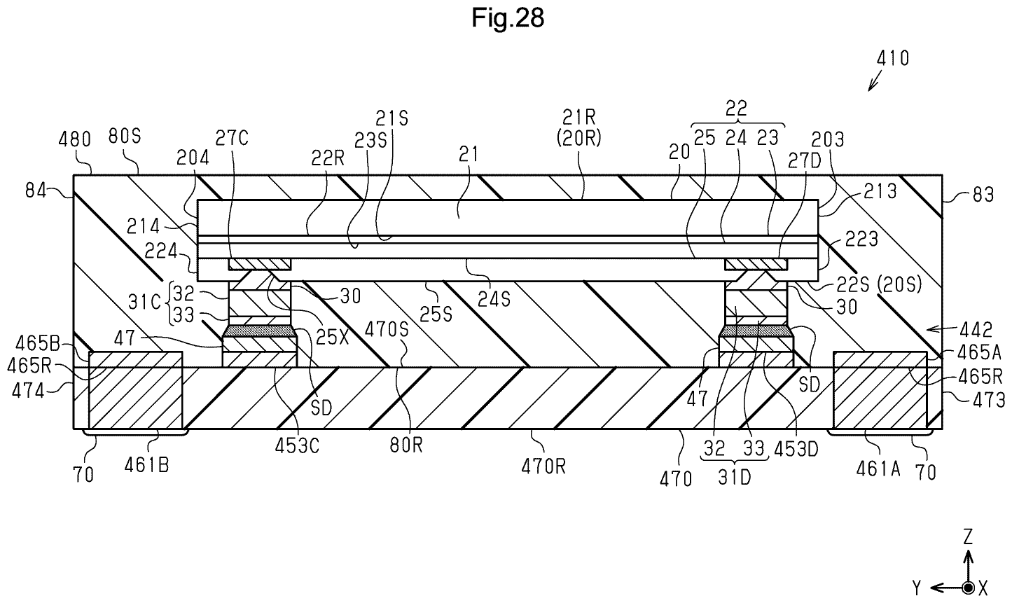

FIGS. 23 and 24 are perspective views showing the exterior of the semiconductor device 410. FIG. 23 is an upper perspective view of the semiconductor device 410, and FIG. 24 is a lower perspective view of the semiconductor device 410. FIG. 25 is a plan view showing the lower side of the semiconductor device 410. In FIGS. 25 and 26, an encapsulation resin 480 is shown transparently. FIG. 26 is a plan view of the conductor 440. FIG. 27 is a schematic cross-sectional view of the semiconductor device 410 taken along line 27-27 in FIG. 25. FIG. 28 is a schematic cross-sectional view of the semiconductor device 410 taken along line 28-28 in FIG. 15. For the sake of convenience, FIGS. 27 and 28 may show a member that is not present on the line indicating the cross-sectional position. Further, the position and size of a member may differ from those shown in FIGS. 25 and 26.

### General Structure of Semiconductor Device

As shown in FIGS. 23 and 24, the semiconductor device 410 is, for example, rectangular-box-shaped.

As shown in FIGS. 23 to 28, the semiconductor device 410 includes the semiconductor element 20, the conductor 440, the encapsulation resin 480, and a resin layer 470.

The conductor 440 includes a second coil 443 and external connection terminals 451A, 451B, 461A, and 461B. The semiconductor element 20 is mounted on the conductor 440. The first coil 26 of the semiconductor element 20 is opposed to the second coil 443 of the conductor 440 in the z-direction. The first coil 26 and the second coil 443 corresponds to the coils 913A and 913B shown in FIG. 1. As shown in FIGS. 24, 25, 27, and 28, the semiconductor device 410 includes an external conductive film 70 covering the external connection terminals 451A, 451B, 461A, and 461B.

The semiconductor device 410 includes the device upper surface 10S, the device lower surface 10R, and the device side surfaces 11, 12, 13, and 14.

### Encapsulation Resin

The encapsulation resin 480 has the form of, for example, a rectangular plate. The encapsulation resin 480 includes the resin upper surface 80S, the resin lower surface 80R, and the resin side surfaces 81 to 84. The resin upper surface 80S of the encapsulation resin 480 defines the device upper surface 10S of the semiconductor device 410.

The encapsulation resin 480 encapsulates the semiconductor element 20, the conductor 440, and the bonding portion SD. The encapsulation resin 480 covers the element front surface 20S, the element back surface 20R, and the element side surfaces 201 to 204 of the semiconductor element 20. Thus, the semiconductor element 20 is embedded in the encapsulation resin 480. The semiconductor element 20 is arranged in the encapsulation resin 480 so that the element front surface 20S and the resin lower surface 80R of the encapsulation resin 480 face in the same direction.

The encapsulation resin 480 is formed from, for example, an electrically insulating resin. The resin may be, for example, a synthetic resin of which the base component is an epoxy resin. The encapsulation resin 480 may be formed from, for example, a synthetic resin including a filler. The filler is formed from, for example, SiO₂. The encapsulation resin 480 is, for example, colored black. The material properties and shape of the encapsulation resin 480 are not limited.

### Resin Layer

The resin layer 470 has the form of, for example, a rectangular plate. In plan view, the resin layer 470 is the same in size as the encapsulation resin 480.

The resin layer 470 is insulating. The resin layer 470 is a base member of the semiconductor device 410. The semiconductor element 20 is mounted on the resin layer 470. The resin layer 470 may be referred to as a support member supporting the semiconductor element 20.

The resin layer 470 includes an upper surface 470S, a lower surface 470R, and side surfaces 471, 472, 473, and 474. The upper surface 470S and the lower surface 470R face in opposite directions in the z-direction. The upper surface 470S of the resin layer 470 is in contact with the resin lower surface 80R of the encapsulation resin 480. The lower surface 470R of the resin layer 470 and the resin lower surface 80R of the encapsulation resin 480 face in the same direction. The side surfaces 471 to 474 of the resin layer 470 intersect the upper surface 470S and the lower surface 470R of the resin layer 470. The side surfaces 471 and 472 of the resin layer 470 face in opposite directions in the x-direction. The side surfaces 473 and 474 of the resin layer 470 face in opposite directions in the y-direction. The lower surface 470R of the resin layer 470 defines the device lower surface 10R of the semiconductor device 410. The resin side surfaces 81 to 84 of the encapsulation resin 480 and the side surfaces 471 to 474 of the resin layer 470 define the device side surfaces 11 to 14 of the semiconductor device 410.

The resin layer 470 is formed from, for example, an electrically insulating resin. The resin may be, for example, a synthetic resin of which the base component is an epoxy resin. The resin layer 470 may be formed from, for example, a synthetic resin including a filler. The filler is formed from, for example, SiO₂. The resin layer 470 is, for example, colored black. The material properties and shape of the resin layer 470 are not limited. The resin layer 470 and the encapsulation resin 480 may be formed from the same material. When the resin layer 470 and the encapsulation resin 480 are formed from the same material, the interface between the encapsulation resin 480 and the resin layer 470 (the resin lower surface 80R of the encapsulation resin 480 and the upper surface 470S of the resin layer 470) may not be formed.

### Conductor

As shown in FIGS. 25 to 28, the conductor 440 includes a first wiring member 441, a second wiring member 442, and the second coil 443. The conductor 440 may be formed from, for example, a plating layer. The conductor 240 is formed from a material including, for example, Cu.

### First Wiring Member

The first wiring member 441 includes a first external connection terminal 451A, a second external connection terminal 451B, a first element connector 453A, a second element connector 453B, a first interconnect 454A, a second interconnect 454B, a first terminal connector 455A, and a second terminal connector 455B. The first element connector 453A, the second element connector 453B, the first interconnect 454A, the second interconnect 454B, the first terminal connector 455A, and the second terminal connector 455B form a first lead wire.

As shown in FIGS. 27 and 28, the first element connector 453A, the first interconnect 454A, and the first terminal connector 455A are formed on the upper surface 470S of the resin layer 470. The first element connector 453A is electrically connected to the first terminal connector 455A by the first interconnect 454A. The first element connector 453A, the first interconnect 454A, and the first terminal connector 455A may be formed integrally as a single body.

As shown in FIGS. 27 and 28, the second element connector 453B, the second interconnect 454B, and the second terminal connector 455B are formed on the upper surface 470S of the resin layer 470. The second element connector 453B is electrically connected to the second terminal connector 455B by the second interconnect 454B. The second element connector 453B, the second interconnect 454B, and the second terminal connector 455B may be formed integrally as a single body.

As shown in FIGS. 25 and 26, the first element connector 453A and the second element connector 453B overlap the semiconductor element 20 in plan view. The first element connector 453A and the second element connector 453B overlap the element electrodes 31A and 31B of the semiconductor element 20 in the z-direction.

The first element connector 453A and the second element connector 453B are quadrilateral in plan view. The shape of the first element connector 453A and the second element connector 453B may be changed in any manner and may be, for example, circular or polygonal in plan view.

As shown in FIG. 27, a barrier layer 47 is formed on the first element connector 453A. The first element connector 453A is electrically connected to the first element electrode 31A of the semiconductor element 20 by the barrier layer 47 and the bonding portion SD. The barrier layer 47 is formed on the second element connector 453B. The second element connector 453B is electrically connected to the second element electrode 31B of the semiconductor element 20 by the barrier layer 47 and the bonding portion SD.

The first external connection terminal 451A is electrically connected to the first terminal connector 455A. The first external connection terminal 451A extends from the first terminal connector 455A toward the resin lower surface 80R of the encapsulation resin 480. The first external connection terminal 451A includes a lower surface 451A1 exposed from the lower surface 470R of the resin layer 470. The second external connection terminal 451B is electrically connected to the second terminal connector 455B. The second external connection terminal 451B extends from the second terminal connector 455B toward the resin lower surface 80R of the encapsulation resin 480. The second external connection terminal 451B includes a lower surface 451B1 exposed from the lower surface 470R of the resin layer 470.

As shown in FIGS. 25 and 26, the first external connection terminal 451A and the second external connection terminal 451B are quadrilateral in plan view. The shape of the first external connection terminal 451A and the second external connection terminal 451B may be changed in any manner and may be, for example, circular or polygonal in plan view.

As shown in FIGS. 25 and 26, in an example, the first external connection terminal 451A and the second external connection terminal 451B are arranged along the device side surface 12 of the semiconductor device 410. The first external connection terminal 451A and the second external connection terminal 451B may be separated in the y-direction. The first external connection terminal 451A and the second external connection terminal 451B are arranged in the y-direction in plan view. The first external connection terminal 451A is located at the corner formed of the device side surface 12 and the device side surface 13 of the semiconductor device 410. The second external connection terminal 451B is located at the corner of the device side surface 12 and the device side surface 14 of the semiconductor device 410.

### Second Wiring Member

As shown in FIGS. 25 to 28, the second wiring member 442 includes a third external connection terminal 461A, a fourth external connection terminal 461B, a third interconnect 464A, a fourth interconnect 464B, a third terminal connector 465A, a fourth terminal connector 465B, and an end connector 466. The third interconnect 464A, the fourth interconnect 464B, the third terminal connector 465A, the fourth terminal connector 465B, and the end connector 466 form a “second lead wire.”

As shown in FIG. 27, the second coil 443 is formed on the upper surface 470S of the resin layer 470. As shown in FIGS. 25 and 26, the second coil 443 is spiral in plan view. As shown in FIG. 25, in plan view, the second coil 443 overlaps the first coil 26 of the semiconductor element 20. The second coil 443 includes a first end 443A located outward and a second end 443B located inward. The first end 443A corresponds to an “outer end.” The second end 443B corresponds to an “inner end.”

As shown in FIGS. 25 and 26, the end connector 466 is arranged at an inner side of the second coil 443. The end connector 466 is electrically connected to the second end 443B of the second coil 443. The first end 443A of the second coil 443 is electrically connected to the third terminal connector 465A by the third interconnect 464A. The second coil 443, the end connector 466, the third interconnect 464A, and the third terminal connector 465A may be formed integrally as a single body.

As shown in FIGS. 25 and 26, the end connector 466 is electrically connected to the fourth terminal connector 465B by the fourth interconnect 464B. As shown in FIG. 27, the fourth interconnect 464B is embedded in the resin layer 470. The fourth interconnect 464B includes an embedded wire 467 and vias 468A connected to opposite ends of the embedded wire 467. The embedded wire 467 includes a first end electrically connected to the end connector 466 by the vias 468A. The embedded wire 467 includes a second end electrically connected to the fourth terminal connector 265B (refer to FIG. 26) by the via 468A.

As shown in FIG. 28, the third external connection terminal 461A is disposed on a lower surface 465R of the third terminal connector 465A. The third external connection terminal 461A is electrically connected to the third terminal connector 465A. The third external connection terminal 461A extends from the third terminal connector 465A toward the lower surface 470R of the resin layer 470. The third external connection terminal 461A includes a lower surface 461A1 exposed from the lower surface 470R of the resin layer 470.

The fourth external connection terminal 461B is disposed on the lower surface 465R of the fourth terminal connector 465B. The fourth external connection terminal 461B is electrically connected to the fourth terminal connector 465B. The fourth external connection terminal 461B extends from the fourth terminal connector 465B toward the lower surface 470R of the resin layer 470. The fourth external connection terminal 461B includes a lower surface 461B1 exposed from the lower surface 470R of the resin layer 470.

As shown in FIGS. 25 and 26, the third external connection terminal 461A and the fourth external connection terminal 461B are quadrilateral in plan view. The shape of the third external connection terminal 461A and the fourth external connection terminal 461B may be changed in any manner and may be, for example, circular or polygonal in plan view.

In an example, the third external connection terminal 461A and the fourth external connection terminal 461B are arranged along the device side surface 11 of the semiconductor device 410. The third external connection terminal 461A and the fourth external connection terminal 461B may be separated in the y-direction. The first external connection terminal 451A and the second external connection terminal 451B are arranged in the y-direction in plan view. The third external connection terminal 461A is located at the corner of the device side surface 11 and the device side surface 13 of the semiconductor device 410. The fourth external connection terminal 461B is located at the corner of the device side surface 11 and the device side surface 14 of the semiconductor device 410.

### Advantages

As described above, the third embodiment has the following advantages.

(3-1) The same advantages as those of the semiconductor device 10 of the first embodiment and the semiconductor device 210 of the second embodiment are obtained.

(3-2) The semiconductor device 410 includes the external connection terminals 451A, 451B, 461A, and 461B extending through the resin layer 470. The device upper surface 10S of the semiconductor device 410 is defined by the resin upper surface 80S of the encapsulation resin 480 encapsulating the semiconductor element 20. This allows for decrease in size (height) as compared to the semiconductor device 210 including the substrate 271 and the substrate insulation film 272.

### Modified Example of Third Embodiment

A semiconductor device in a modified example of the third embodiment will now be described. In the semiconductor device of the modified example, the same reference characters are given to those components that are the same as the corresponding components of the third embodiment. Such components will not be described in detail.

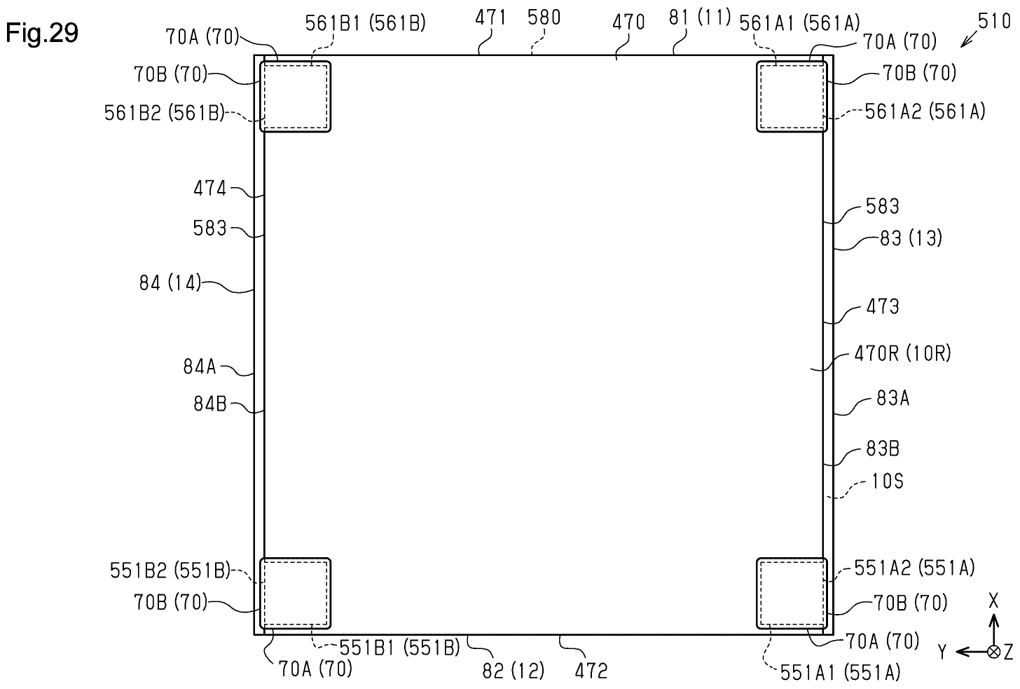

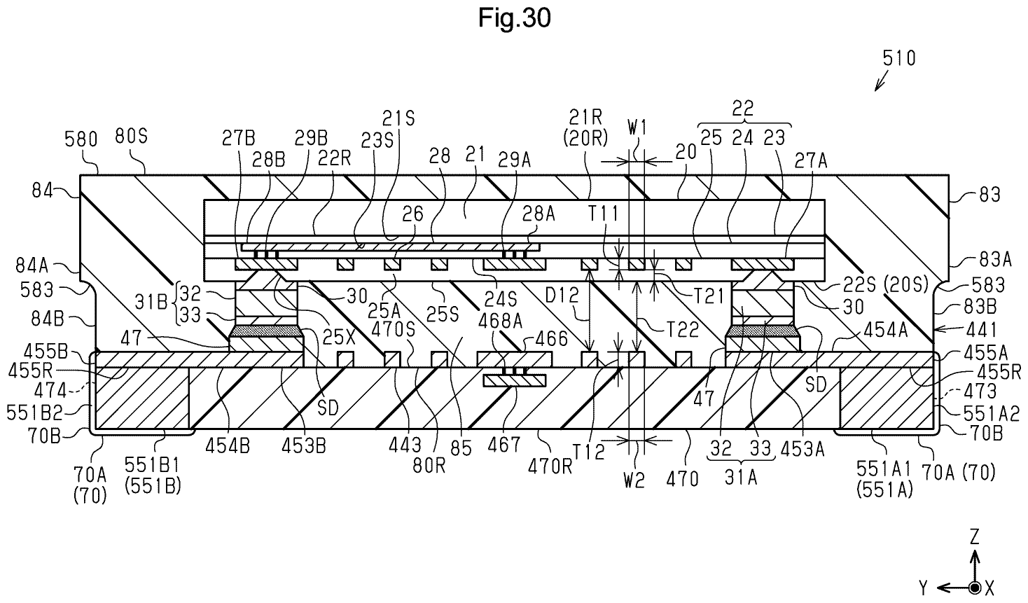

As shown in FIGS. 29 and 30, a semiconductor device 510 includes an encapsulation resin 580. The resin side surfaces 83 and 84 of the encapsulation resin 580 include first side surfaces 83A and 84A and second side surfaces 83B and 84B. The first side surfaces 83A and 84A are located closer to the resin upper surface 80S than to the resin lower surface 80R in the z-direction. The second side surfaces 83B and 84B are located closer to the resin lower surface 80R than to the resin upper surface 80S in the z-direction. The second side surfaces 83B and 84B of the resin side surfaces 83 and 84 are located inward of the encapsulation resin 580 with respect to the first side surfaces 83A and 84A of the resin side surfaces 83 and 84. In other words, in the z-direction, the encapsulation resin is greater in size at the side of the resin upper surface 80S than at the side of the resin lower surface 80R.

The first side surfaces 83A and 84A of the resin side surfaces 83 and 84 are orthogonal to the resin upper surface 80S. The second side surfaces 83B and 84B of the resin side surfaces 83 and 84 are orthogonal to the resin lower surface 80R. The encapsulation resin 580 includes a step 583 recessed inward of the encapsulation resin 580 at the first side surfaces 83A and 84A and the second side surfaces 83B and 84B of the resin side surfaces 83 and 84 in plan view. The step 583 may be disposed in the resin side surfaces 81 to 84.

The resin layer 470 is the same in size as the resin lower surface 80R of the encapsulation resin 580 in the z-direction. Thus, as viewed in the z-direction, the side surfaces 473 and 474 of the resin layer 470 facing in the y-direction are located inward of the resin layer 470 with respect to the first side surfaces 83A and 84A of the encapsulation resin 580. In a case where the step 583 is disposed in the resin side surfaces 81 and 82, the positions of the side surfaces 471 and 472 are changed accordingly.

As shown in FIGS. 29 and 30, the first external connection terminal 551A is exposed from the side surface 473 of the resin layer 470 in the y-direction. More specifically, the first external connection terminal 551A is exposed in the lower surface 470R and the side surface 473 of the resin layer 470. The first external connection terminal 551A includes a lower surface 551A1 and a side surface 551A2 exposed from the resin layer 470. The lower surface 551A1 and the side surface 551A2 of the first external connection terminal 551A are covered by the external conductive film 70. The external conductive film 70 includes the first conductive film 70A, which covers the lower surface 551A1 of the first external connection terminal 551A, and the second conductive film 70B, which covers the side surface 551A2 of the first external connection terminal 551A.

The second external connection terminal 551B is exposed from the side surface 474 of the resin layer 470 in the y-direction. More specifically, the second external connection terminal 551B is exposed in the lower surface 470R and the side surface 474 of the resin layer 470. The second external connection terminal 551B includes a lower surface 551B1 and a side surface 551B2 exposed from the resin layer 470. The lower surface 551B1 and the side surface 551B2 of the second external connection terminal 551B are covered by the external conductive film 70. The external conductive film 70 includes the first conductive film 70A, which covers the lower surface 551B1 of the second external connection terminal 551B, and the second conductive film 70B, which covers the side surface 551B2 of the first external connection terminal 551A.

As shown in FIG. 29, a third external connection terminal 561A is exposed from the side surface 473 of the resin layer 470 in the y-direction. More specifically, the third external connection terminal 561A is exposed in the lower surface 470R and the side surface 473 of the resin layer 470. The third external connection terminal 561A includes a lower surface 561A1 and a side surface 561A2 exposed from the resin layer 470. The lower surface 561A1 and the side surface 561A2 of the third external connection terminal 561A are covered by the external conductive film 70. The external conductive film 70 includes the first conductive film 70A, which covers the lower surface 561A1 of the third external connection terminal 561A, and the second conductive film 70B, which covers the side surface 561A2 of the first external connection terminal 551A.

A fourth external connection terminal 561B is exposed from the side surface 474 of the resin layer 470 in the y-direction. More specifically, the fourth external connection terminal 561B is exposed in the lower surface 470R and the side surface 474 of the resin layer 470. The fourth external connection terminal 561B includes a lower surface 561B1 and a side surface 561B2 exposed from the resin layer 470. The lower surface 561B1 and the side surface 561B2 of the fourth external connection terminal 561B are covered by the external conductive film 70. The external conductive film 70 includes the first conductive film 70A, which covers the lower surface 561B1 of the fourth external connection terminal 561B, and the second conductive film 70B, which covers the lower surface 561B2 of the first external connection terminal 551A.

The semiconductor device 510 of the modified example is mounted on the substrate 920 shown in FIG. 2. In this case, when the external connection terminals 551A, 551B, 561A, and 561B are connected to mount pads of the substrate 920 by solder, the solder adheres to the first conductive film 70A and the second conductive film 70B covering the external connection terminals 551A, 551B, 561A, and 561B. More specifically, for example, in a reflow process, solder is in a liquid state and flows upward on the second conductive film 70B to form a fillet between the second conductive film 70B and the mount pads. Thus, the semiconductor device 510 facilitates formation of a solder fillet. The solder fillet increases the area bonded by solder, thereby increasing the connection strength. In addition, the soldering state of the semiconductor device 510 is readily checked based on the solder fillet.

In FIGS. 29 and 30, the external connection terminals 551A and 561A are exposed from the side surface 473 of the resin layer 470. The external connection terminals 551B and 561B are exposed in the side surface 474 of the resin layer 470. The side surface from which the external connection terminals 551A, 551B, 561A, and 561B are exposed may be changed in any manner. In an example, while the external connection terminals 551A and 551B are exposed in the side surface 472 of the resin layer 470, the external connection terminals 561A and 561B may be exposed in the side surface 471 of the resin layer 470. The external connection terminal 551A may be exposed in two side surfaces located adjacent to each other (e.g., the side surface 472 and the side surface 473 of the resin layer 470). Also, the external connection terminals 551B, 561A, and 561B may be exposed in two side surfaces located adjacent to each other.

### Other Modified Examples

The embodiments may be, for example, modified as described below. The above embodiment and the modified examples described below may be combined as long as there is no technical contradiction. In the following modified examples, the same reference characters are given to those components that are the same as the corresponding components of the above embodiments. Such components will not be described in detail.

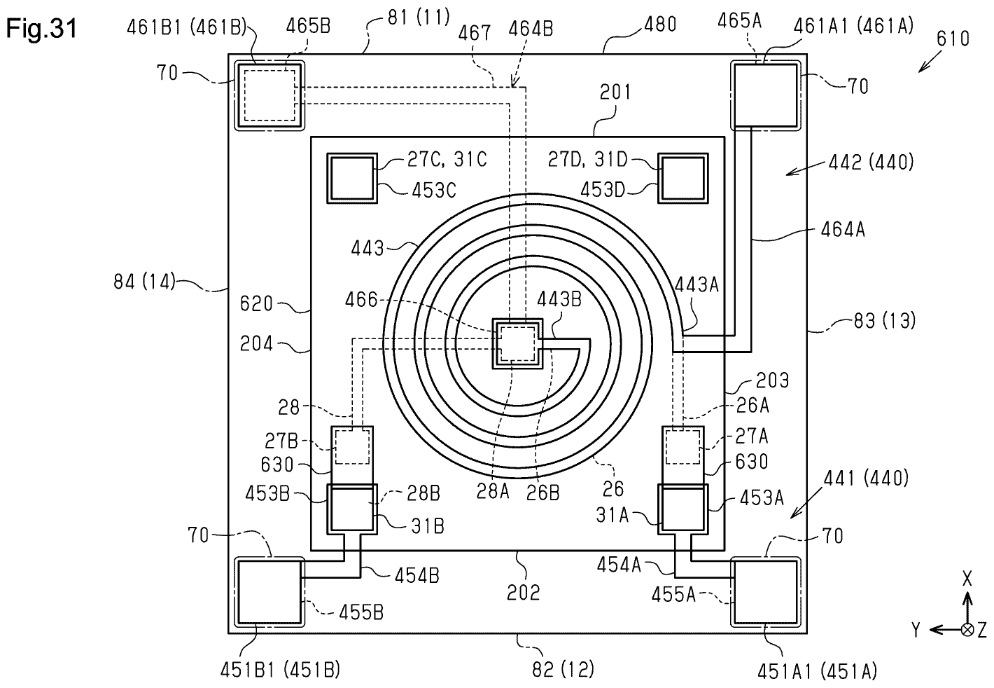

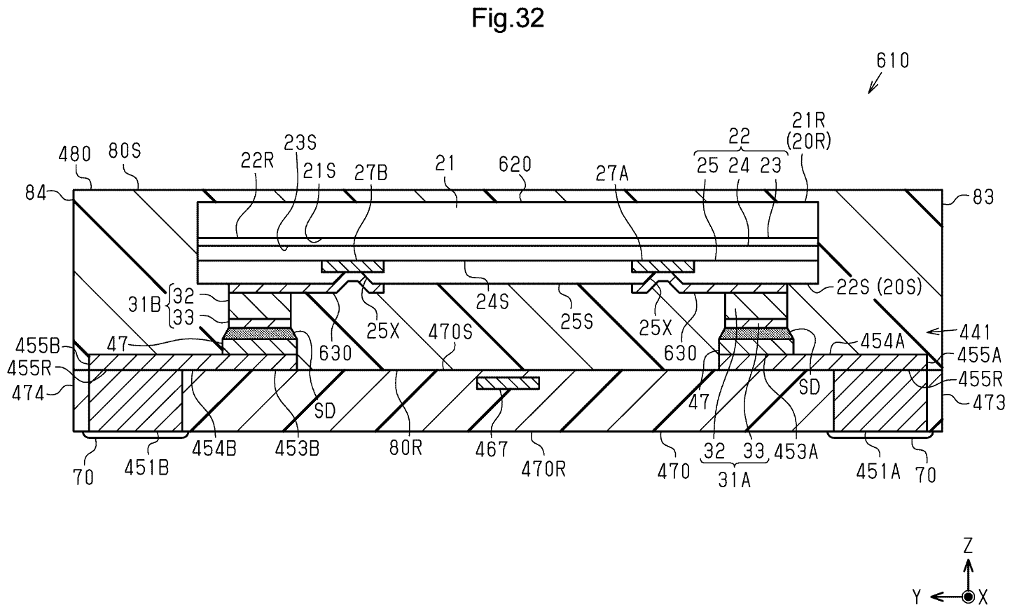

In the semiconductor devices 10, 110, 210, 310, 410, and 510 of the embodiments and modified examples described above, the shape of the overall structure and the layout and shape of the terminals may be changed in any manner. In an example, FIGS. 31 and 32 show a modified example of the semiconductor device 410 of the third embodiment. FIG. 31 is a plan view showing the lower side of a modified example of a semiconductor device 610. FIG. 32 is a schematic cross-sectional view of the semiconductor device 610 of the modified example showing external connection terminals 451A and 451B connected to a semiconductor element 620.

As shown in FIGS. 31 and 32, as viewed in the z-direction, the element electrodes 31A and 31B and the connection pads 27A and 27B are located at different positions. Interconnects 630 are electrically connected to the connection pads 27A and 27B exposed from the openings 25X in the third insulation layer 25 of the element insulation layer 22. The interconnect 630 extends from the connection pads 27A and 27B to the insulation front surface 22S of the element insulation layer 22. The interconnect 630 may be referred to as a redistribution layer. The element electrodes 31A and 31B are each electrically connected to a portion of the interconnect 630 disposed on the insulation front surface 22S of the element insulation layer 22.

In FIG. 31, in plan view, the element electrodes 31C and 31D overlap the connection pads 27C and 27D. Alternatively, the element electrodes 31C and 31D may be arranged so as not to overlap the connection pads 27C and 27D in the same manner as the element electrodes 31A and 31B.

The transformer 913 shown in FIG. 1 may be changed to a semiconductor element capacitor chip that uses a capacitor to insulate the first circuit 911 and the second circuit 912. The capacitor chip including a capacitor is an example of a semiconductor device having an isolation configuration.

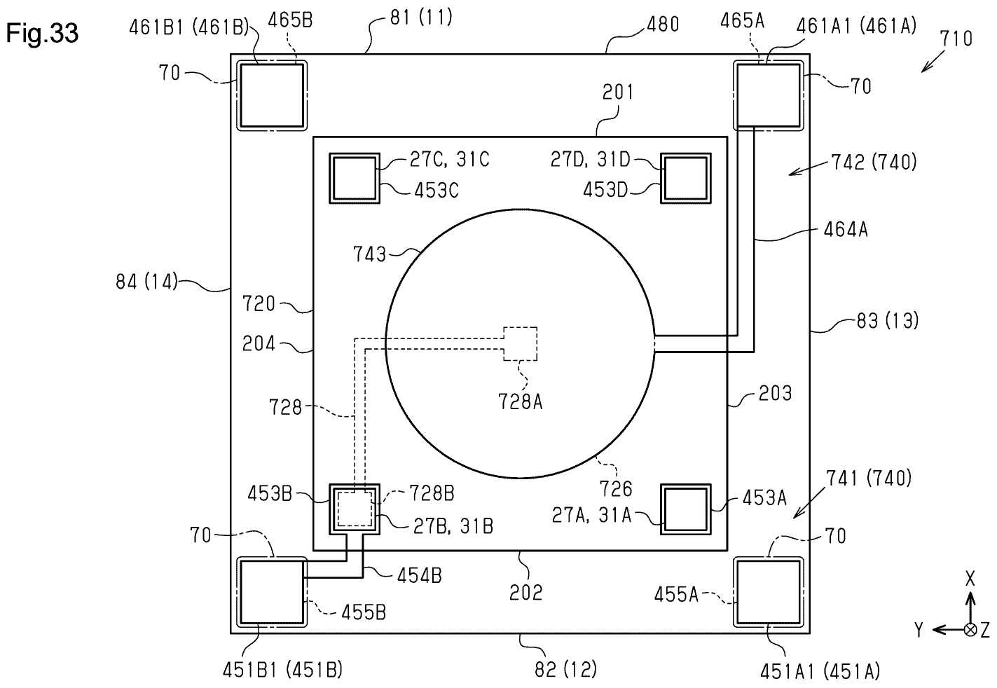

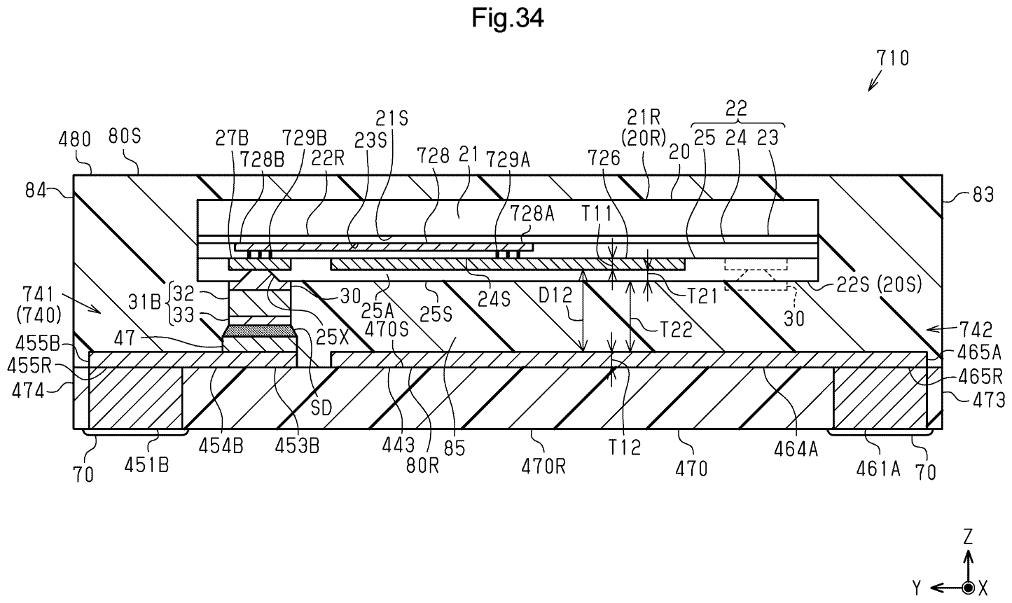

FIG. 33 is a schematic plan view of a semiconductor device 710 including a capacitor. FIG. 34 is a schematic cross-sectional view of the semiconductor device 710 shown in FIG. 33.

The semiconductor device 710 includes a semiconductor element 720. The semiconductor element 720 includes a first electrode plate 726. The first electrode plate 726 is electrically connected to the element electrode 31B by an element interconnect 728. The element interconnect 728 includes a first end 728A electrically connected to the first electrode plate 726 by a via 729A. The element interconnect 728 includes a second end 728B electrically connected to the connection pad 27B by a via 729B. The element electrode 31B is connected to the connection pad 27B.

A second electrode plate 743 is disposed on the upper surface 470S of the resin layer 470 of the semiconductor device 710. A conductor 740 includes a first wiring member 741, a second wiring member 742, and a second electrode plate 743. The first wiring member 741 includes a first external connection terminal 451A, a second external connection terminal 451B, a first element connector 453A, a second element connector 453B, a second interconnect 454B, a first terminal connector 455A, and a second terminal connector 455B. The second wiring member 742 includes the third external connection terminal 461A, the fourth external connection terminal 461B, the third interconnect 464A, the third terminal connector 465A, and the fourth terminal connector 465B.

The first electrode plate 726 and the second electrode plate 743 are opposed to each other in the z-direction. The first electrode plate 726 and the second electrode plate 743 form a capacitor. In other words, a semiconductor device may be a capacitor chip including a capacitor. The first electrode plate 726 corresponds to a “first conductor.” The second electrode plate 743 corresponds to a “second conductor.”

In an example, the element electrode 31B is electrically connected to the second external connection terminal 451B by the second element connector 453B, the second interconnect 454B, and the second terminal connector 455B, which form the first wiring member 741 of the conductor 740. In an example, the second electrode plate 743 is electrically connected to the third external connection terminal 461A by the third interconnect 464A and the third terminal connector 465A, which form the second wiring member 742 of the conductor 740. External connection terminals connected to the first electrode plate 726 and the second electrode plate 743 may be changed in any manner.

The semiconductor device 710 of the modified example obtains the same advantages as those of the semiconductor device 10 of the first embodiment.

The semiconductor devices described in the embodiments and modified examples use a first coil and a second coil to transmit signals. The semiconductor devices may be used in other application. The semiconductor device may be used in, for example, a DC voltage conversion circuit (DC-DC converter), a digital isolator, or an isolated AD converter circuit.

In the present disclosure, the term “on” includes the meaning of “above” in addition to the meaning of “on” unless otherwise clearly indicated in the context. Accordingly, the phrase of “first layer formed on second layer” may mean that the first layer is formed directly contacting the second layer in one embodiment and that the first layer is located above the second layer without contacting the second layer in another embodiment. Thus, the word “on” will also allow for a structure in which another layer is arranged between the first layer and the second layer.

The z-axis direction as referred to in the present disclosure does not necessarily have to be the vertical direction and does not necessarily have to fully conform to the vertical direction. In the structures according to the present disclosure (e.g., the structure shown in FIG. 1), “upward” and “downward” in the z-axis direction as referred to in the present description are not limited to “upward” and “downward” in the vertical direction. For example, the X-axis direction may be the vertical direction. Alternatively, the Y-axis direction may be the vertical direction.

### Clauses

Technical concepts that can be understood from each of the above embodiments and modified examples will now be described. It should be noted that, for the purpose of facilitating understanding with no intention to limit, elements described in clauses are given the reference characters of the corresponding elements of the embodiments. The reference signs are used as examples to facilitate understanding, and the elements in each clause are not limited to those elements given with the reference signs.
[Clause 1]

A semiconductor device, including:
a semiconductor element (20) including an element front surface (20S) and an element back surface (20R) facing in opposite directions in a thickness-wise direction (z), the semiconductor element (20) further including an element insulation layer (22) including an insulation front surface (22S) defining the element front surface (20S) and a first conductor (26) disposed in the element insulation layer (22);
a second conductor (43) separated from the first conductor (26) in the thickness-wise direction (z); and
an encapsulation resin (80) in contact with the element insulation layer (22) and encapsulating the semiconductor element (20) and the second conductor (43),
where the first conductor (26) and the second conductor (43) are located at opposite sides of the element insulation layer (22) and the encapsulation resin (80) and are opposed to each other in the thickness-wise direction (z).
[Clause 2]

The semiconductor device according to clause 1, where the semiconductor element (20) includes element side surfaces (201 to 204) each intersecting the element front surface (20S) and the element back surface (20R), and the encapsulation resin (80) covers the element back surface (20R) and the element side surfaces (201 to 204).
[Clause 3]

The semiconductor device according to clause 1 or 2, where the encapsulation resin (80) is greater in thickness than the element insulation layer (22).
[Clause 4]

The semiconductor device according to any one of clauses 1 to 3, where the second conductor (43) is greater in thickness than the first conductor (26).
[Clause 5]

The semiconductor device according to any one of clauses 1 to 4, where the encapsulation resin (80) includes a resin lower surface (80R) facing in a same direction as the element front surface (20S), the semiconductor device, further including:
a first wiring member (41) electrically connected to the first conductor (26) and exposed from the resin lower surface (80R); and
a second wiring member (42) electrically connected to the second conductor (43) and exposed from the resin lower surface (80R).
[Clause 6]

The semiconductor device according to clause 5, where
the semiconductor element (20) includes an element electrode (31A, 31B) electrically connected to the first conductor (26),
the first wiring member (41) includes:
   a first lead wire (253A, 253B, 254A, 254B, 255A, 255B) embedded in the encapsulation resin (80) and electrically connected to the element electrode (31A, 31B); and
   a first external connection terminal electrically connected to the first lead wire (253A, 253B, 254A, 254B, 255A, 255B) and exposed from the resin lower surface (80R).
[Clause 7]

The semiconductor device according to clause 6, where the first lead wire (253A, 253B, 254A, 254B, 255A, 255B) includes an element connector (53A, 53B) connected to the element electrode (31A, 31B) and an interconnect electrically connecting the element connector (53A, 53B) and the first external connection terminal.
[Clause 8]

The semiconductor device according to clause 6 or 7, where at least a portion of the first external connection terminal does not overlap the semiconductor element (20) as viewed in the thickness-wise direction (z).
[Clause 9]

The semiconductor device according to any one of clauses 5 to 8, where the second wiring member (42) includes:
a second lead wire (64) embedded in the encapsulation resin (80) and electrically connected to the second conductor (43); and
a second external connection terminal electrically connected to the second lead wire (64) and exposed from the resin lower surface (80R).
[Clause 10]

The semiconductor device according to clause 9, where the second conductor (43) and the second lead wire (64) are embedded in the encapsulation resin (80) at a same position in the thickness-wise direction (z).
[Clause 11]

The semiconductor device according to any one of clauses 5 to 10, where
the second wiring member (42) is electrically connected to an outer end of the second conductor (43), and
the second wiring member (42) includes a third external connection terminal electrically connected to an inner end of the second conductor (43) and exposed from the resin lower surface (80R).
[Clause 12]

The semiconductor device according to any one of clauses 5 to 11, where the second conductor (43) and the second wiring member (42) include a lead frame.
[Clause 13]

The semiconductor device according to clause 12, where
the semiconductor element (20) includes a dummy element electrode (31C, 31D) (31A, 31B) electrically insulated from the first conductor (26), and
the lead frame includes a dummy element connector (53A, 53B) (53C, 53D) connected to the dummy element electrode (31C, 31D) (31A, 31B).
[Clause 14]

The semiconductor device according to any one of clauses 1 to 4, including:
a substrate including an upper surface and a lower surface; and
a substrate insulation film disposed on the lower surface of the substrate, where
the second conductor (43) is disposed on a lower surface of the substrate insulation film, and
the encapsulation resin (80) is in contact with the lower surface of the substrate insulation film.
[Clause 15]

The semiconductor device according to clause 14, where the encapsulation resin (80) includes a resin lower surface (80R) facing in a same direction as the lower surface of the substrate, the semiconductor device, including:
a first wiring member (41) electrically connected to the first conductor (26) and exposed from the resin lower surface (80R); and
a second wiring member (42) electrically connected to the second conductor (43) and exposed from the resin lower surface (80R).
[Clause 16]

The semiconductor device according to clause 15, where
the semiconductor element (20) includes an element electrode (31A, 31B) electrically connected to the first conductor (26), and
the first wiring member (41) includes:
   a first lead wire (253A, 253B, 254A, 254B, 255A, 255B) disposed on a lower surface of the substrate insulation film and electrically connected to the element electrode (31A, 31B); and
   a first external connection terminal electrically connected to the first lead wire (253A, 253B, 254A, 254B, 255A, 255B) and extending through the encapsulation resin (80) and being exposed from the resin lower surface (80R).
[Clause 17]

The semiconductor device according to clause 16, where the first lead wire (253A, 253B, 254A, 254B, 255A, 255B) includes an element connector (53A, 53B) connected to the element electrode (31A, 31B), a terminal connector connected to the first external connection terminal, and an interconnect electrically connecting the element connector (53A, 53B) and the terminal connector.
[Clause 18]

The semiconductor device according to clause 16 or 17, where the first external connection terminal does not overlap the semiconductor element (20) as viewed in the thickness-wise direction (z).
[Clause 19]

The semiconductor device according to any one of clauses 15 to 18, where the second wiring member (42) includes:
a second lead wire (264A, 264B, 265A, 265B) disposed on a lower surface of the substrate insulation film and electrically connected to the second conductor (43); and
a second external connection terminal electrically connected to the second lead wire (264A, 264B, 265A, 265B) and extending through the encapsulation resin (80) in the thickness-wise direction (z) and being exposed from the resin lower surface (80R).
[Clause 20]

The semiconductor device according to clause 19, where the second lead wire includes a terminal connector (265A, 265B) connected to the second external connection terminal and an interconnect (264A, 264B) electrically connecting the second conductor (43) and the terminal connector.
[Clause 21]

The semiconductor device according to clause 19 or 20, where the second external connection terminal does not overlap the semiconductor element (20) as viewed in the thickness-wise direction (z).
[Clause 22]

The semiconductor device according to any one of clauses 15 to 21, where the semiconductor element (20) includes a dummy element electrode (31C, 31D) (31A, 31B) electrically insulated from the first conductor (26), the semiconductor device, including:
a dummy element connector (53A, 53B) (53C, 53D) disposed on a lower surface of the substrate insulation film and connected to the dummy element electrode (31C, 31D) (31A, 31B).
[Clause 23]

The semiconductor device according to any one of clauses 1 to 4, where the encapsulation resin (80) includes a resin lower surface (80R) facing in a same direction as the element front surface (20S), the semiconductor device, including:
a resin layer including an upper surface in contact with the resin lower surface (80R),
where the second conductor (43) is disposed on the upper surface of the resin layer.
[Clause 24]

The semiconductor device according to clause 23, where the resin layer includes a lower surface facing in a same direction as the element front surface (20S), the semiconductor device, including:
a first wiring member (41) electrically connected to the first conductor (26) and exposed from the lower surface of the resin layer; and
a second wiring member (42) electrically connected to the second conductor (43) and exposed from the lower surface of the resin layer.
[Clause 25]

The semiconductor device according to clause 24, where
the semiconductor element (20) includes an element electrode (31A, 31B) electrically connected to the first conductor (26),
the first wiring member (41) includes:
   a first lead wire (253A, 253B, 254A, 254B, 255A, 255B) disposed on the upper surface of the encapsulation resin (80) and electrically connected to the element electrode (31A, 31B); and
   a first external connection terminal electrically connected to the first lead wire (253A, 253B, 254A, 254B, 255A, 255B) and extending through the resin layer in the thickness-wise direction (z) and being exposed from the lower surface of the resin layer.
[Clause 26]

The semiconductor device according to clause 25, where the first lead wire (253A, 253B, 254A, 254B, 255A, 255B) includes an element connector (53A, 53B) connected to the element electrode (31A, 31B), a terminal connector connected to the first external connection terminal, and an interconnect electrically connecting the element connector (53A, 53B) and the terminal connector.
[Clause 27]

The semiconductor device according to clause 25 or 26, where the first external connection terminal does not overlap the semiconductor element (20) as viewed in the thickness-wise direction (z).
[Clause 28]

The semiconductor device according to any one of clauses 24 to 27, where the second wiring member (42) includes:
a second lead wire disposed on a lower surface of the encapsulation resin (80) and electrically connected to the second conductor (43); and
a second external connection terminal electrically connected to the second lead wire and extending through the resin layer in the thickness-wise direction (z) and exposed from the upper surface.
[Clause 29]

The semiconductor device according to clause 28, where the second lead wire includes a terminal connector connected to the second external connection terminal and an interconnect electrically connecting the second conductor (43) and the terminal connector.
[Clause 30]

The semiconductor device according to clause 28 or 29, where the second external connection terminal does not overlap the semiconductor element (20) as viewed in the thickness-wise direction (z).
[Clause 31]

The semiconductor device according to any one of clauses 24 to 30, where the semiconductor element (20) includes a dummy element electrode (31C, 31D) (31A, 31B) electrically insulated from the first conductor (26), the semiconductor device, including: a dummy element connector (53A, 53B) (53C, 53D) disposed on the lower surface of the resin layer and connected to the dummy element electrode (31C, 31D) (31A, 31B).
[Clause 32]

The semiconductor device according to any one of clauses 1 to 31, where
the first conductor (26) includes a first coil that is spiral as viewed in the thickness-wise direction (z), and
the second conductor (43) includes a second coil that is spiral as viewed in the thickness-wise direction (z).
[Clause 33]

The semiconductor device according to clause 32, where
the first coil has a first width-wise dimension in a direction parallel to the element front surface (20S),
the second coil has a second width-wise dimension in a direction parallel to the element front surface (20S), and
the second width-wise dimension is larger than the first width-wise dimension.
[Clause 34]

The semiconductor device according to any one of clauses 1 to 31, where
the first conductor (26) includes a first electrode plate extending parallel to the element front surface (20S),
the second conductor (43) includes a second electrode plate extending parallel to the element front surface (20S), and
the first electrode plate and the second electrode plate form a capacitor.
[Clause 35]

A semiconductor device, including:
a semiconductor element (20) including an element front surface (20S) and an element back surface (20R) facing in opposite directions in a thickness-wise direction (z), element side surfaces (201 to 204) each intersecting the element front surface (20S) and the element back surface (20R), a first coil (26) that is spiral as viewed in the thickness-wise direction (z), and an element electrode (31A, 31B) electrically connected to the first coil (26);
a conductor including a first wiring member (41) electrically connected to the element electrode (31A, 31B) by a bonding portion, a second coil (43) opposed to the first coil (26), and a second wiring member (42) electrically connected to the second coil (43); and
an encapsulation resin (80) including a resin lower surface (80R) facing in a same direction as the element front surface (20S) and encapsulating the semiconductor element (20) and the conductor,
where the first wiring member (41) and the second wiring member (42) include an external connection terminal exposed from the resin lower surface (80R).
[Clause 36]

A semiconductor device, including:
a semiconductor element (20) including an element front surface (20S) and an element back surface (20R) facing in opposite directions in a thickness-wise direction (z), element side surfaces (201 to 204) each intersecting the element front surface (20S) and the element back surface (20R), a first coil (26) that is spiral as viewed in the thickness-wise direction (z), and an element electrode (31A, 31B) electrically connected to the first coil (26);
a semiconductor substrate including a lower surface opposed to the element front surface (20S);
a substrate insulation film formed on the lower surface of the semiconductor substrate and including a lower surface opposed to the element front surface (20S);
a conductor formed on the lower surface of the substrate insulation film and including a first wiring member (41) electrically connected to the element electrode (31A, 31B) by a bonding portion, a second coil (243) opposed to the first coil (26), and a second wiring member (42) electrically connected to the second coil (243); and
an encapsulation resin (80) including a lower surface facing in a same direction as the element back surface (20R), the encapsulation resin (80) filling a gap between the semiconductor element (20) and the substrate insulation film and encapsulating the semiconductor element (20),
where the first wiring member (41) and the second wiring member (42) include an external connection terminal exposed from the lower surface of the encapsulation resin (80).
[Clause 37]

A semiconductor device, including:
a semiconductor element (20) including an element front surface (20S) and an element back surface (20R) facing in opposite directions in a thickness-wise direction (z), element side surfaces (201 to 204) each intersecting the element front surface (20S) and the element back surface (20R), a first coil (26) that is spiral as viewed in the thickness-wise direction (z), and an element electrode (31A, 31B) electrically connected to the first coil (26);
a resin layer including an upper surface and a lower surface facing opposite directions, the lower surface being opposed to the element front surface (20S) in the thickness-wise direction (z);
a first external connection terminal extending through the resin layer;
a second external connection terminal extending through the resin layer;
a conductor formed on the upper surface of the resin layer and including a first wiring member (41) electrically connected to the first external connection terminal, a second wiring member (42) electrically connected to the second external connection terminal, and a second coil (443) opposed to the first coil (26) and electrically connected to the second wiring member (42);
a bonding portion electrically connecting the first wiring member (41) and the element electrode (31A, 31B); and
an encapsulation resin (80) filling a gap between the semiconductor element (20) and the resin layer and encapsulating the semiconductor element (20).

The description above illustrates examples. One skilled in the art may recognize further possible combinations and replacements of the components and methods (manufacturing processes) in addition to those listed for purposes of describing the techniques of the present disclosure. The present disclosure is intended to include any substitute, modification, changes included in the scope of the disclosure including the claims.

What is claimed is:

1. A semiconductor device, comprising:
a semiconductor element including an element front surface and an element back surface facing in opposite directions in a thickness-wise direction, the semiconductor element further including an element insulation layer including an insulation front surface defining the element front surface and a first conductor disposed in the element insulation layer;
a second conductor separated from the first conductor in the thickness-wise direction; and
an encapsulation resin in contact with the element insulation layer and encapsulating the semiconductor element and the second conductor,
wherein the first conductor and the second conductor are located at opposite sides of the element insulation layer and the encapsulation resin and are opposed to each other in the thickness-wise direction.

2. The semiconductor device according to claim 1, wherein
the semiconductor element includes element side surfaces each intersecting the element front surface and the element back surface, and
the encapsulation resin covers the element back surface and the element side surfaces.

3. The semiconductor device according to claim 1, wherein the encapsulation resin is greater in thickness than the element insulation layer.

4. The semiconductor device according to claim 1, wherein the second conductor is greater in thickness than the first conductor.

5. The semiconductor device according to claim 1, wherein the encapsulation resin includes a resin lower surface facing in a same direction as the element front surface, the semiconductor device, further comprising:
a first wiring member electrically connected to the first conductor and exposed from the resin lower surface; and
a second wiring member electrically connected to the second conductor and exposed from the resin lower surface.

6. The semiconductor device according to claim 5, wherein
the semiconductor element includes an element electrode electrically connected to the first conductor, and
the first wiring member includes:
a first lead wire embedded in the encapsulation resin and electrically connected to the element electrode; and
a first external connection terminal electrically connected to the first lead wire and exposed from the resin lower surface.

7. The semiconductor device according to claim 6, wherein the first lead wire includes an element connector connected to the element electrode and an interconnect electrically connecting the element connector and the first external connection terminal.

8. The semiconductor device according to claim 6, wherein at least a portion of the first external connection terminal does not overlap the semiconductor element as viewed in the thickness-wise direction.

9. The semiconductor device according to claim 5, wherein the second wiring member includes:
a second lead wire embedded in the encapsulation resin and electrically connected to the second conductor; and
a second external connection terminal electrically connected to the second lead wire and exposed from the resin lower surface.

10. The semiconductor device according to claim 1, further comprising:
a substrate including an upper surface and a lower surface; and
a substrate insulation film disposed on the lower surface of the substrate, wherein
the second conductor is disposed on a lower surface of the substrate insulation film, and
the encapsulation resin is in contact with the lower surface of the substrate insulation film.

11. The semiconductor device according to claim 10, wherein the encapsulation resin includes a resin lower surface facing in a same direction as the lower surface of the substrate, the semiconductor device, further comprising:
a first wiring member electrically connected to the first conductor and exposed from the resin lower surface; and
a second wiring member electrically connected to the second conductor and exposed from the resin lower surface.

12. The semiconductor device according to claim 11, wherein
the semiconductor element includes an element electrode electrically connected to the first conductor,
the first wiring member includes:
a first lead wire disposed on a lower surface of the substrate insulation film and electrically connected to the element electrode; and
a first external connection terminal electrically connected to the first lead wire and extending through the encapsulation resin and being exposed from the resin lower surface.

13. The semiconductor device according to claim 12, wherein the first lead wire includes an element connector connected to the element electrode, a terminal connector connected to the first external connection terminal, and an interconnect electrically connecting the element connector and the terminal connector.

14. The semiconductor device according to claim 12, wherein the first external connection terminal does not overlap the semiconductor element as viewed in the thickness-wise direction.

15. The semiconductor device according to claim 1, wherein the encapsulation resin includes a resin lower surface facing in a same direction as the element front surface, the semiconductor device, further comprising:
a resin layer including an upper surface in contact with the resin lower surface,
wherein the second conductor is disposed on the upper surface of the resin layer.

16. The semiconductor device according to claim 15, wherein the resin layer includes a lower surface facing in a same direction as the element front surface, the semiconductor device, further comprising:
a first wiring member electrically connected to the first conductor and exposed from the lower surface of the resin layer; and
a second wiring member electrically connected to the second conductor and exposed from the lower surface of the resin layer.

17. The semiconductor device according to claim 16, wherein
the semiconductor element includes an element electrode electrically connected to the first conductor, and
the first wiring member includes:
a first lead wire disposed on the upper surface of the encapsulation resin and electrically connected to the element electrode; and
a first external connection terminal electrically connected to the first lead wire and extending through the resin layer in the thickness-wise direction and being exposed from the lower surface of the resin layer.

18. The semiconductor device according to claim 17, wherein the first lead wire includes an element connector connected to the element electrode, a terminal connector connected to the first external connection terminal, and an interconnect electrically connecting the element connector and the terminal connector.

19. The semiconductor device according to claim 17, wherein the first external connection terminal does not overlap the semiconductor element as viewed in the thickness-wise direction.

20. The semiconductor device according to claim 1, wherein
the first conductor includes a first coil that is spiral as viewed in the thickness-wise direction, and
the second conductor includes a second coil that is spiral as viewed in the thickness-wise direction.
